(19) United States
(12) Patent Application Publication
(10) Pub. No.: US 2026/0018196 A1
(43) Pub. Date: Jan. 15, 2026

(54) MULTI-CHANNEL MEMORY STACK WITH SHARED DIE

(71) Applicant: Rambus Inc., San Jose, CA (US)

(72) Inventors: Dongyun LEE, Sunnyvale, CA (US); Wendy ELSASSER, Austin, TX (US); Taeksang SONG, San Jose, CA (US)

(21) Appl. No.: 18/994,560

(22) PCT Filed: Sep. 5, 2023
(86) PCT No.: PCT/US2023/031970

§ 371 Date: Jan. 14, 2025

Related U.S. Application Data
(60) Provisional application No. 63/404,662, filed on Sep. 8, 2022.

(51) Int. Cl. G11C 7/10; G11C 5/06; G11C 7/22; G11C 29/02

(52) U.S. Cl. CPC G11C 7/1069; G11C 5/066; G11C 7/22; G11C 29/022

(57) ABSTRACT

An interconnected stack of Dynamic Random Access Memory (DRAM) die has a first set of DRAM die (e.g., two, three, four, etc.) coupled to a first independent memory channel, a second set of DRAM die (e.g., two, three, four, etc.) coupled to a second independent memory channel, and a shared die coupled to both independent memory channels. The shared die may be used to store information (e.g., error correcting code) for Reliability, Availability, and Serviceability (RAS) purposes. The shared die may also be used to replace the functionality of a failed or failing die.

### BRIEF DESCRIPTION OF THE DRAWINGS

FIGS. 1A-1B are diagrams illustrating a first example memory system.

FIGS. 2A-2B are diagrams illustrating a second example memory system.

FIGS. 3A-3C are diagrams illustrating memory device stack data bursts.

FIG. 4 is a block diagrams illustrating a first example memory device.

FIG. 5 is a block diagrams illustrating a second example memory device.

FIG. 6 is a block diagram illustrating a first example memory devices with configurable command/address processing delays.

FIG. 7 is a block diagram illustrating a second example memory devices with configurable command/address processing delays.

FIG. 8 is a block diagram illustrating example system connections for a memory device stack.

FIGS. 9A-9B are diagrams illustrating a first example data strobe provisioning for a memory device stack.

FIGS. 10A-10B are diagrams illustrating a second example data strobe provisioning for a memory device stack.

FIG. 11 is a flowchart illustrating a method of operating an integrated circuit stack.

FIG. 12 is a flowchart illustrating a method of communicating data bursts from multiple memory devices in a memory device stack.

FIG. 13 is a flowchart illustrating a method of providing data strobes for a data burst.

FIG. 14 is a flowchart illustrating a first example method of time multiplexing accesses to multiple memory devices in a memory device stack.

FIG. 15 is a flowchart illustrating a second example method of time multiplexing accesses to multiple memory devices in a memory device stack.

FIG. 16 is a flowchart illustrating a first example method of replacing the functionality of a failed memory device in a memory device stack.

FIG. 17 is a flowchart illustrating a first example method of replacing the functionality of a failed memory device in a memory device stack.

FIG. 18 is an illustration of a data burst having an error correction code.

FIG. 19 is a block diagram illustrating example system connections for a memory device stack.

FIG. 20 is a diagram illustrating memory device stack data bursts.

FIG. 21 is a block diagram of a processing system.

### DETAILED DESCRIPTION OF THE EMBODIMENTS

In an embodiment, an interconnected stack of Dynamic Random Access Memory (DRAM) die has a first set of DRAM die (e.g., two, three, four, etc.) coupled to a first independent memory channel, a second set of DRAM die (e.g., two, three, four, etc.) coupled to a second independent memory channel, and a shared die coupled to both independent memory channels. The shared die may be used to store information (e.g., error correcting code) for Reliability, Availability, and Serviceability (RAS) purposes. The shared die may also be used to replace the functionality of a failed or failing die.

In an embodiment, the first set of DRAM die, second set of DRAM die, and the shared die communicate with a memory controller using data bursts. The shared die receives the same commands/addresses, at the same time, as received by both the first set of DRAM die and the second DRAM die. In an embodiment, the shared die is configured to communicate on one of the two data bytes of the first independent memory channel after one of the first set of DRAM die has communicated on that byte. Likewise, the shared die is configured to communicate on one of the two data bytes of the second independent memory channel after one of the second set of DRAM die has communicated on that byte. Thus, in other words, the shared die is configured to send its data burst after the data bursts of the first and second sets of DRAM die.

In another embodiment, one of the first set of DRAM die communicates a partial data burst before the shared die starts communicating on the same byte. That die then waits for the other byte to be available (i.e., another die finishes its data burst) and then finishes its burst on the other byte. Thus, it should be understood that data communicated with the shared die is time-multiplexed with data communicated with one or more dies in the sets of DRAM die. In an embodiment, in order to accomplish the time-multiplexing of data between the shared die and dies in the sets of DRAM die, the shared die is configured to delay processing the commands/addresses by the amount of time (e.g., clock cycles) needed for the other dies to complete their bursts or partial bursts.

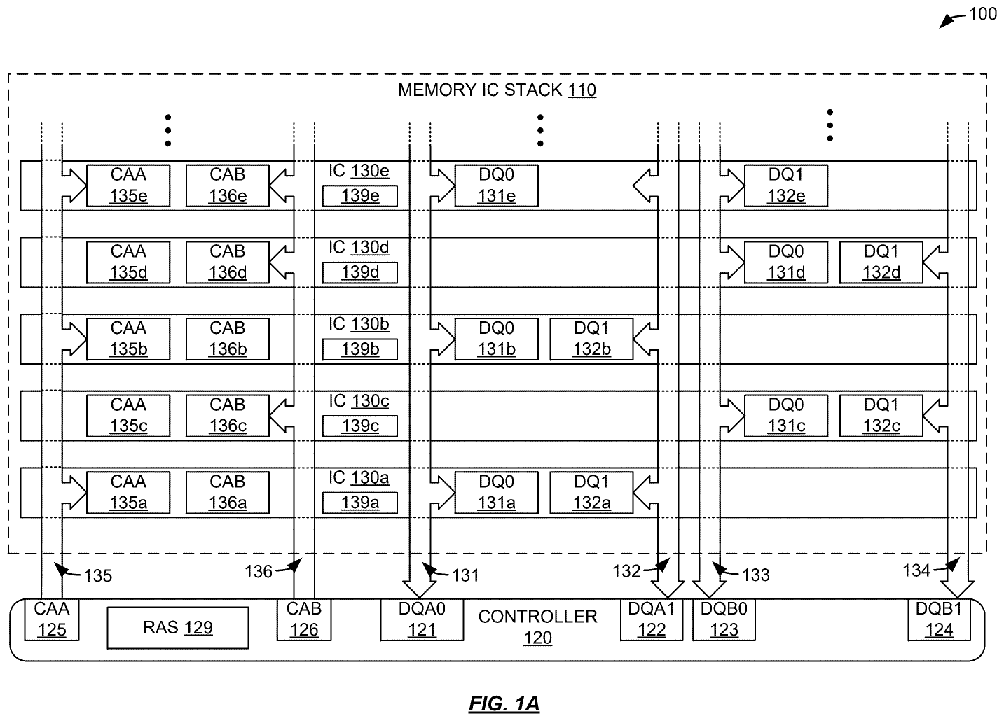

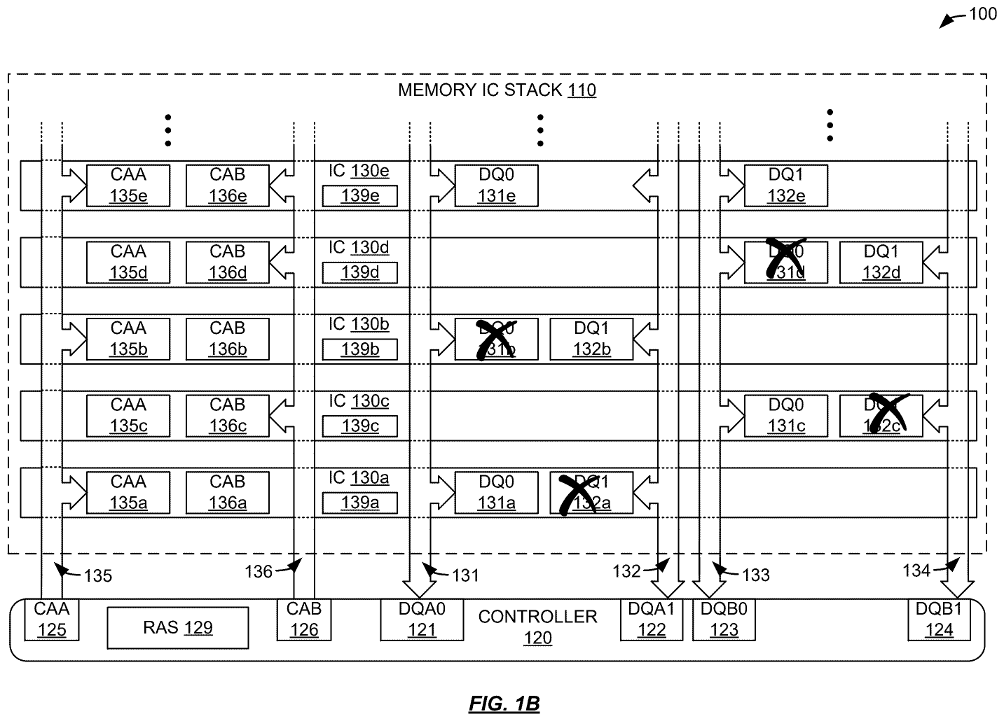

FIGS. 1A-1B are diagrams illustrating a first example memory system. In FIGS. 1A-1B, memory system 100 comprises stacked die component 110 and controller 120. Stacked die component 110 comprises memory integrated circuit (IC) dies 130a-130e, command/address “A” (CAA) interface 135, command/address “B” (CAB) interface 136, channel “A” first bit group (DQA0) interface 131, channel “A” second bit group (DQA1) interface 132, channel “B” first bit group (DQB0) interface 133, channel “B” second bit group (DQB1) interface 134. In an embodiment, channel A first bit group and channel B first bit group correspond to the least significant bits (e.g., lower DQs or lower nibble, byte, word, etc.) of channel A and channel B, respectively. Likewise, channel A second bit group and channel B second bit group correspond to the most significant bits (e.g., upper DQs or upper nibble, byte, word, etc.) of channel A and channel B, respectively.

Each of DRAM integrated circuit die 130a-130e respectively include first bit group (DQ0) interface 131a-131e, second bit group (DQ1) interface 132a-132e, command/address “A” (CAA) interface 135a-135e, command/address “B” (CAB) interface 136a-136e, and at least one memory array 139a-139e. Controller 120 includes channel “A” first bit group (DQA0) interface 121, channel “A” second bit group (DQA1) interface 122, channel “B” first bit group (DQB0) interface 123, channel “B” first bit group (DQA1) interface 124, channel “A” command/address (CAA) interface 125, channel “B” command/address (CAB) interface 126, and Reliability, Availability, and Serviceability (RAS) circuitry 129. In an embodiment, the DQ0 interfaces 131a-131e, DQ1 interfaces 132a-132e, DQA0 interface 121, DQA1 interface 122, DQB0 interface 123, and DQB1 interface 124, DQA0 interface 131, DQA1 interface 132, DQB0 interface 133, and DQB1 interface 134 are each 8 bits (1 byte) wide.

Controller 120 and DRAM integrated circuit die 130a-130e are integrated circuit type devices, such as those commonly referred to as “chips”. A memory controller, such as controller 120, manages the flow of data going to and from memory devices. Functionality of a memory controller may be included on a single die with a microprocessor, or included as part of a more complex integrated circuit system as a block of a system on a chip (SOC). For example, a memory controller may be a northbridge chip, an application specific integrated circuit (ASIC) device, a load-reduction memory buffer, a graphics processor unit (GPU), a system-on-chip (SoC) or an integrated circuit device that includes many circuit blocks such as ones selected from graphics cores, processor cores, and MPEG encoder/decoders, etc.

Controller 120, stacked die component 110, and integrated circuit die 130a-130e may be interconnected with each other in a variety of system topologies including on a PC board (e.g., where stacked die component 110 is on a module and controller 120 is socketed to the PC board, or in “die-down” arrangement where one or more of the components are soldered to the PC board). Stacked die component 110 comprises a stack of DRAM integrated circuit die 130a-130e co-packaged together and coupled to each other and/or controller 120 via wired bonds and/or through-silicon vias (TSVs). In an embodiment, all DRAM IC dies 130a-130e in stacked die component 110 may be identical. In various embodiments, controller 120 may or may not be included in stacked die component 110 with DRAM IC dies 130a-130e.

CAA interface 125 of controller 120 is operatively coupled (e.g., connected) to the CAA interface 135a of DRAM IC die 130a, CAA interface 135b of DRAM IC die 130b, and CAA interface 135e of DRAM IC die 130e via CAA interface 135 of stacked die component 110. CAB interface 126 of controller 120 is operatively coupled to the CAB interface 136c of DRAM IC die 130c, CAB interface 136d of DRAM IC die 130d, and CAB interface 136e of DRAM IC die 130e via CAB interface 136 of stacked die component 110.

DQA0 interface 121 of controller 120 is operatively coupled to DQ0 interface 131a of DRAM IC die 130a, DQ0 interface 131b of DRAM IC die 130b, and DQ0 interface 131e of DRAM IC die 130e via DQA0 interface 131 of stacked die component 110. DQA1 interface 122 of controller 120 is operatively coupled to DQ1 interface 132a of DRAM IC die 130a, and DQ1 interface 132b of DRAM IC die 130b via DQA1 interface 132 of stacked die component 110. DQB0 interface 123 of controller 120 is operatively coupled to DQ0 interface 131c of DRAM IC die 130c, DQ0 interface 131d of DRAM IC die 130d, and DQ1 interface 132e of DRAM IC die 130e via DQB0 interface 133 of stacked die component 110. DQB1 interface 124 of controller 120 is operatively coupled to DQ1 interface 132c of DRAM IC die 130c, and DQ1 interface 132d of DRAM IC die 130d via DQB1 interface 134 of stacked die component 110.

In an embodiment, DQ1 interface 132a of DRAM IC die 130a, DQ0 interface 131b of DRAM IC die 130b, DQ1 interface 132c of DRAM IC die 130c, and DQ0 interface 131d of DRAM IC die 130d are disabled. DQ1 interface 132a of DRAM IC die 130a, DQ0 interface 131b of DRAM IC die 130b, DQ1 interface 132c of DRAM IC die 130c, and/or DQ0 interface 131d of DRAM IC die 130d may be disabled, for example, by controller 120 using a mode setting command (e.g., Mode Register Set command—a.k.a., MRS command) transmitted via CAA interface 125 and/or CAB interface 126. In another example, DQ1 interface 132a of DRAM IC die 130a, DQ0 interface 131b of DRAM IC die 130b, DQ1 interface 132c of DRAM IC die 130c, and/or DQ0 interface 131d of DRAM IC die 130d may be disabled by inputting (e.g., by wirebond connections to the positive and/or negative—e.g., ground—supply voltage) one or more logic values to DRAM ICs 130a-130e. Memory system 100 being configured with DQ1 interface 132a of DRAM IC die 130a, DQ0 interface 131b of DRAM IC die 130b, DQ1 interface 132c of DRAM IC die 130c, and/or DQ0 interface 131d of DRAM IC die 130d disabled is illustrated in FIG. 1B by the X's over DQ1 interface 132a of DRAM IC die 130a, DQ0 interface 131b of DRAM IC die 130b, DQ1 interface 132c of DRAM IC die 130c, and DQ0 interface 131d of DRAM IC die 130d.

It should be understood that CAA interface 125 of controller 120, CAA interface 135a of DRAM IC die 130a, CAA interface 135b of DRAM IC die 130b, CAA interface 135e of DRAM IC die 130e, DQA0 interface 121 of controller 120, DQ0 interface 131a of DRAM IC die 130a, DQ1 interface 132b of DRAM IC die 130b, and DQ0 interface 131e of DRAM IC die 130e may comprise, for example, a 16 bit wide memory channel (a.k.a., channel “A”). DRAM IC die 130a may be, for example, configured (e.g., by controller 120) to communicate 8 bits of read and write data with DQA0 interface 121 of controller 120. Similarly, DRAM IC die 130b may be, for example, configured (e.g., by controller 120) to communicate 8 bits of read and write data with DQA1 interface 122 of controller 120. DRAM IC die 130e may be, for example, configured (e.g., by controller 120) to communicate 8 bits of read and write data with DQA0 interface 121 of controller 120.

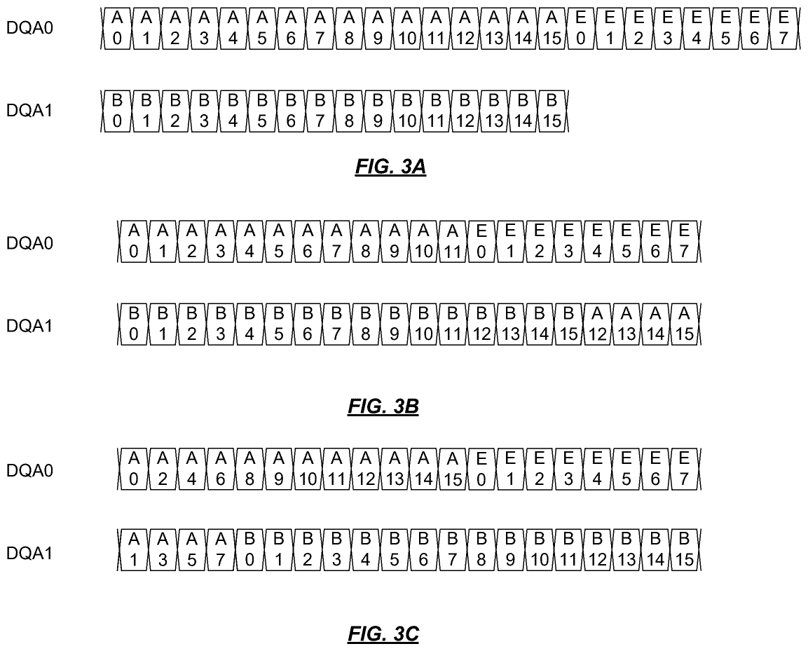

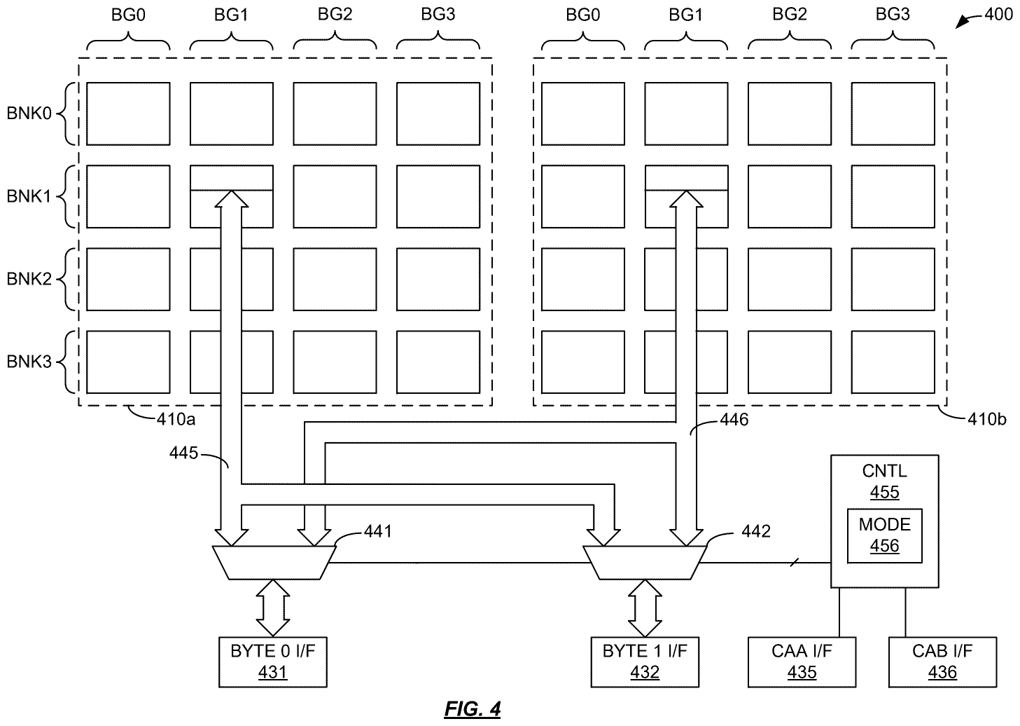

In an embodiment, DRAM IC die 130e is also configured to delay processing commands received via CAA interface 135e by an amount of time (e.g., clock cycles) that allows DRAM IC die 130a to complete communicating a data burst (e.g., 16 bytes) via DQA0 interface 121 before DRAM IC die 130e begins communicating a data burst (e.g., 8 bytes) via DQA0 interface 121. DRAM IC die 130b communicates a data burst (e.g., 16 bytes) via the DQA1 interface 122. This communication via the DQA0 interface 121 with DRAM IC die 130a and DRAM IC die 130e, and the communication via the DQA1 interface 122 with DRAM IC die 130b is illustrated in FIG. 3A. In FIGS. 3A-3C the data bursts communicated with DRAM IC die 130a is labeled with the letter “A”; the data burst communicated with DRAM IC die 130b is labeled with the letter “B”; and the data burst communicated with DRAM IC die 130e is labeled with the letter “E”.

In another embodiment, DRAM IC die 130a communicates a partial data burst (e.g., 12 bytes) and then stops communicating as DRAM IC die 130e starts communicating (e.g., 8 bytes). After DRAM IC die 130b completes communicating a data burst (e.g., 16 bytes) via DQA1 interface 122, DRAM IC die 130a restarts communicating via DQA1 interface 122 until the data burst is complete (e.g., an additional 4 bytes). By selecting the appropriately sized partial burst, DRAM IC die 130a and DRAM IC die 130e may both complete communicating at the same time (i.e., clock cycle). Example communications of a partial data burst via the DQA0 interface 121 with DRAM IC die 130a, the communication of a full data burst with DRAM IC die 130e, the communication via the DQA1 interface 122 with DRAM IC die 130b, and the remaining communication with DRAM IC die 130a via the DQA1 interface 122 are illustrated in FIGS. 3B-3C.

It should be understood that CAB interface 126 of controller 120, CAB interface 136c of DRAM IC die 130c, CAB interface 135d of DRAM IC die 130d, CAB interface 136e of DRAM IC die 130e, DQB0 interface 123 of controller 120, DQ0 interface 131c of DRAM IC die 130c, DQ1 interface 132d of DRAM IC die 130d, and DQ1 interface 132e of DRAM IC die 130e may comprise, for example, a 16 bit wide memory channel (a.k.a., channel “B”). DRAM IC die 130c may be, for example, configured (e.g., by controller 120) to communicate 8 bits of read and write data with DQB0 interface 123 of controller 120. Similarly, DRAM IC die 130d may be configured, for example, (e.g., by controller 120) to communicate 8 bits of read and write data with DQB1 interface 124 of controller 120. DRAM IC die 130e may be configured, for example, (e.g., by controller 120) to communicate 8 bits of read and write data with DQB0 interface 123 of controller 120.

In an embodiment, DRAM IC die 130e is also configured to delay processing commands received via CAB interface 136e by an amount of time (e.g., clock cycles) that allows DRAM IC die 130c to complete communicating a data burst (e.g., 16 bytes) via DQB0 interface 123 before DRAM IC die 130e begins communicating a data burst (e.g., 8 bytes) via DQB0 interface 123. DRAM IC die 130d communicates a data burst (e.g., 16 bytes) via the DQB1 interface 124. This communication via the DQB0 interface 123 with DRAM IC die 130c and DRAM IC die 130e, and the communication via the DQB1 interface 124 with DRAM IC die 130b is similar to the communication illustrated in FIG. 3A.

In another embodiment, DRAM IC die 130c communicates a partial data burst (e.g., 12 bytes) and then stops communicating as DRAM IC die 130e starts communicating (e.g., 8 bytes). After DRAM IC die 130c completes communicating a data burst (e.g., 16 bytes) via DQB1 interface 123, DRAM IC die 130c restarts communicating via DQB1 interface 124 until the data burst is complete (e.g., an additional 4 bytes). By selecting the appropriately sized partial burst, DRAM IC die 130c and DRAM IC die 130e may both complete communicating at the same time (i.e., clock cycle). Example communications of a partial data burst via the DQB0 interface 123 with DRAM IC die 130c, the communication of a full data burst with DRAM IC die 130e, the communication via the DQB1 interface 124 with DRAM IC die 130d, and the remaining communication with DRAM IC die 130c via the DQB1 interface 124 is similar to the communications illustrated in FIGS. 3B-3C.

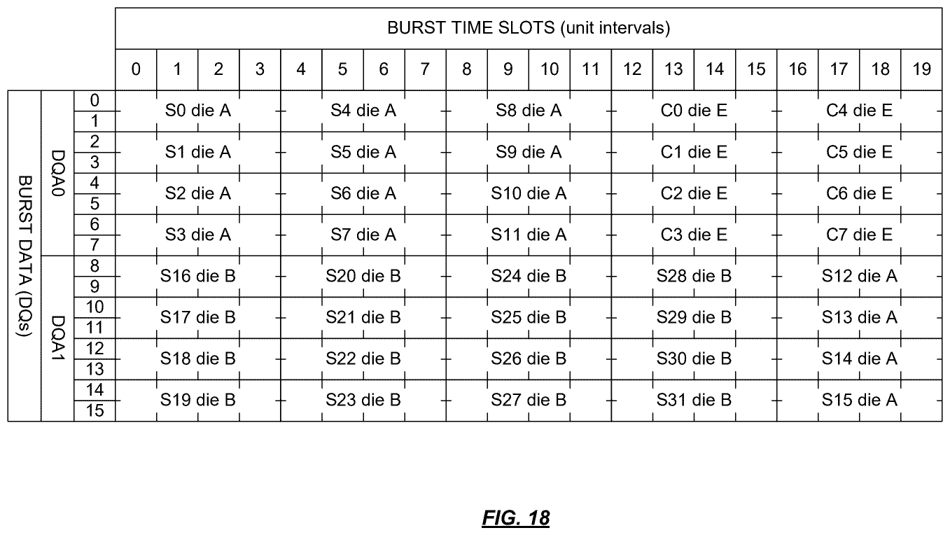

In an embodiment, DRAM ICs 130a-130d are configured to communicate using data bursts that are 16 bytes in length and DRAM IC die 130e is configured to communicate using an 8 byte data burst. The 16 byte bursts communicated by DRAM ICs 130a-130d are used (e.g., by controller 120) to communicate data stored by DRAM ICs 130a-130d. The 8 byte bursts communicated by DRAM IC die 130e may be used to store RAS data (e.g., Reed-Solomon, parity, cyclic redundancy check, etc.), and/or metadata. FIG. 18 illustrates an example data burst (similar to the burst illustrated in FIG. 3B with 32 data symbols (S0-S31) being communicated with (and thus stored by) DRAM IC die 130a and DRAM IC die 130b and 8 check symbols (C0-C7) being communicated with (and thus stored by) DRAM IC die 130e. FIG. 18 also illustrates which DRAM IC die 130a-130e (e.g., “die A” means DRAM IC die 130a) is communicating via which data signals. It should be understood that RAS 129 may generate check symbols (C0-C7) and check data symbols (S0-S31) and check symbols (C0-C7) illustrated in FIG. 18. It should also be understood that FIG. 18 is compatible with, and thus may be, a Reed-Solomon code with symbols size of 8 bits, 40 bytes total, and 32 data bytes—a.k.a., RS(40,32)].

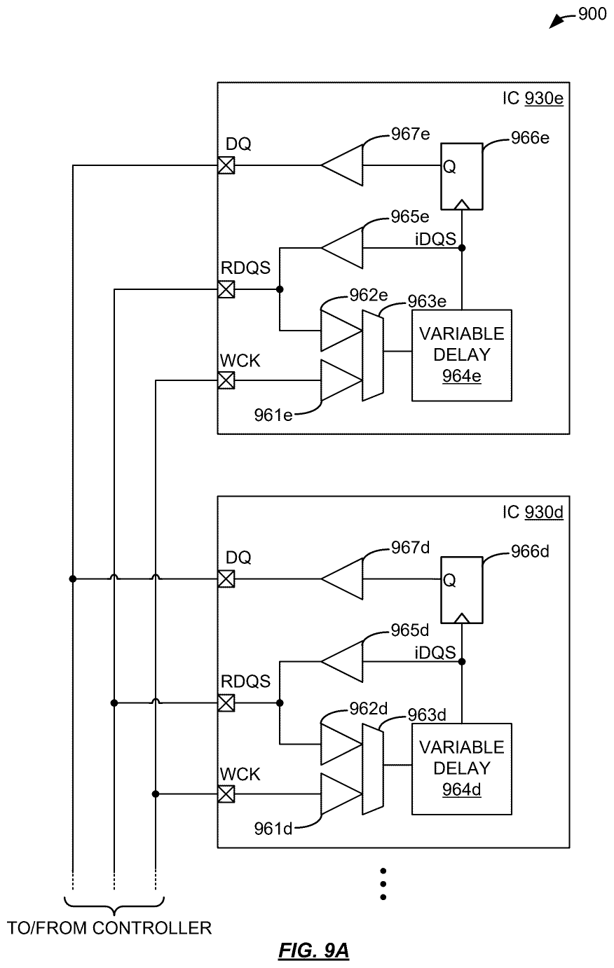

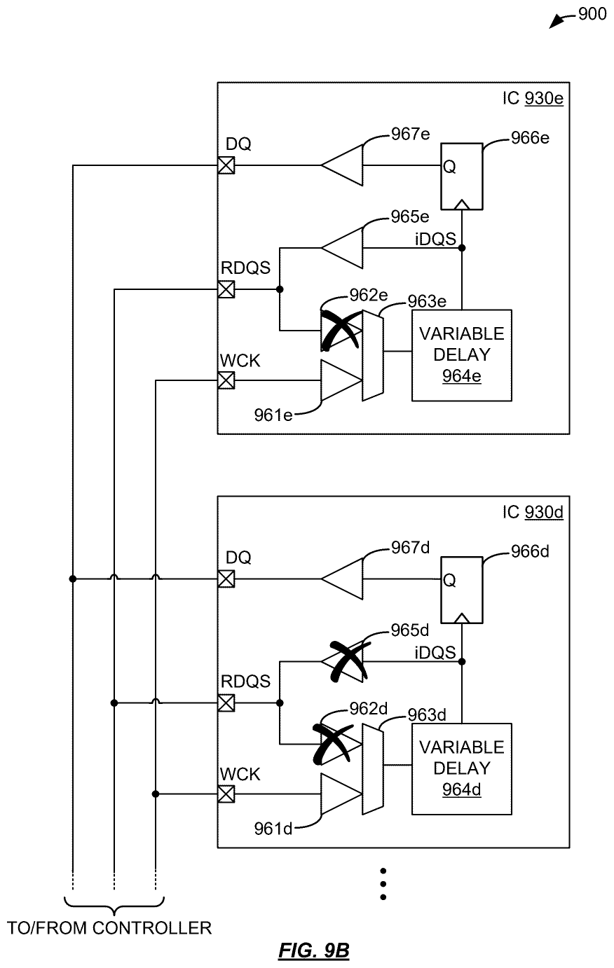

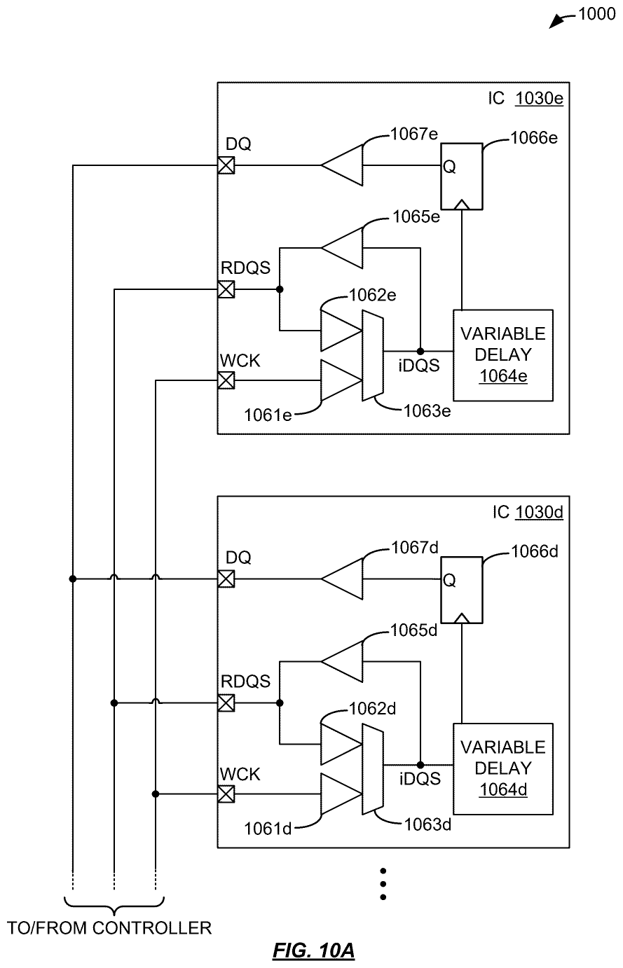

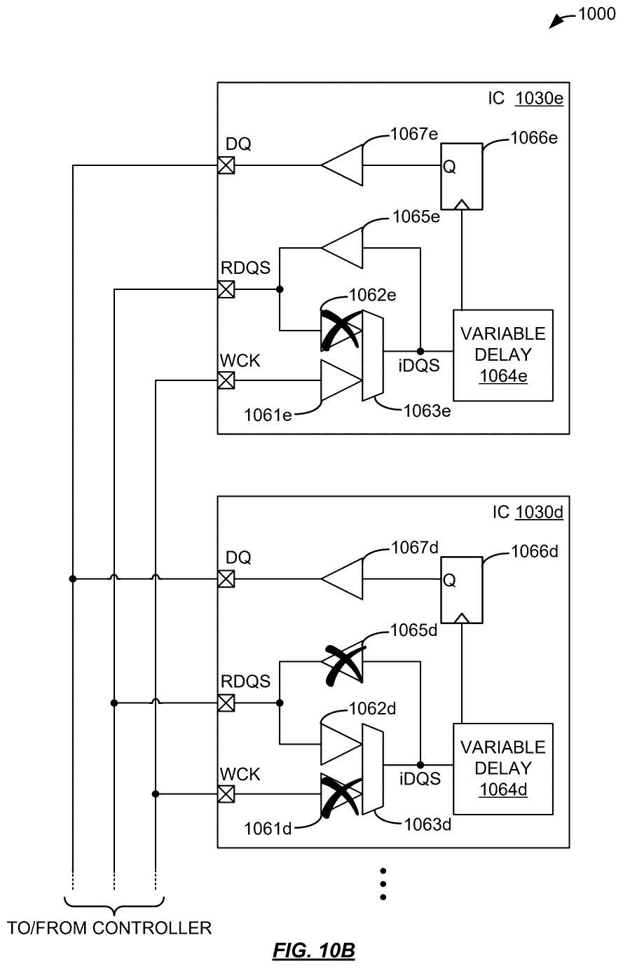

In an embodiment, RAS circuitry 129 may detect that one of DRAM ICs 130a-130d has consistent failures of four symbols. In response to this event, RAS circuitry 129 may disable the failing die, and reconfigure DRAM IC die 130e to function as the disabled die. Controller 120 may then change the RAS scheme from RS(40,32) to a system-wide error correcting code (ECC) scheme. DRAM IC die 130e may be used to replace the failing die. The non-failing die in the same channel (A or B) may be reconfigured to use a different data interface (e.g., swap from using DQA0 to using DQA1) because the connections used by DRAM IC die 130e (a.k.a., the “ECC” die) are fixed. Also, the generation of any timing signals generated by DRAM IC die 130e may be disabled (see, e.g., discussion herein relating to FIGS. 9A-9B and FIGS. 10A-10B). Also, DRAM IC die 130e may be reconfigured to provide data bursts having the same length (e.g., 16 bytes) previously provided by the failing die.

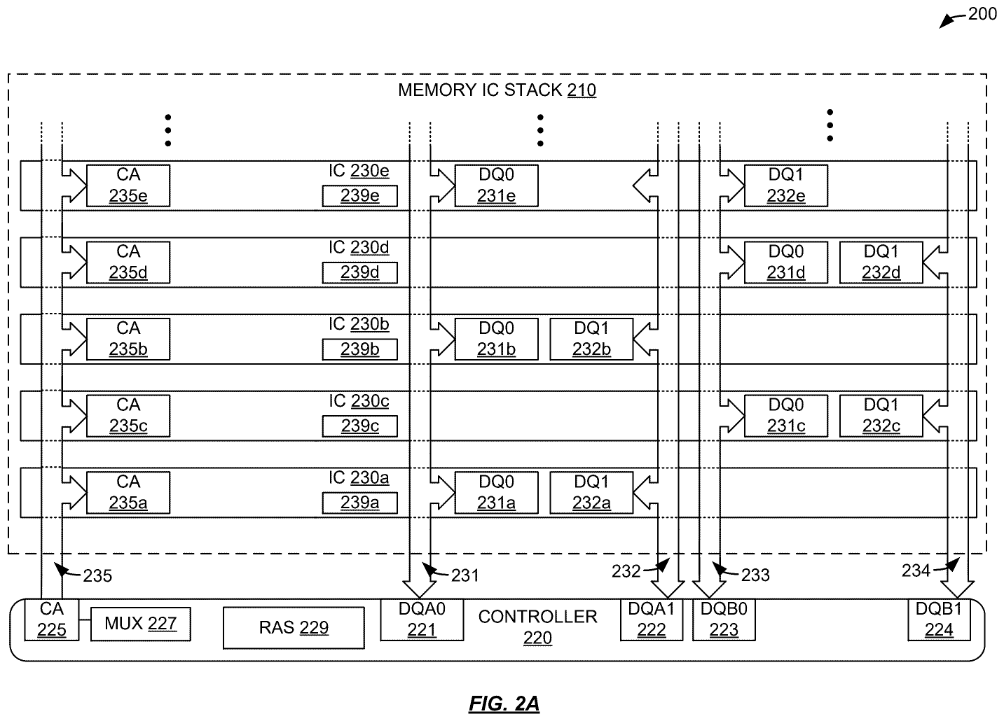

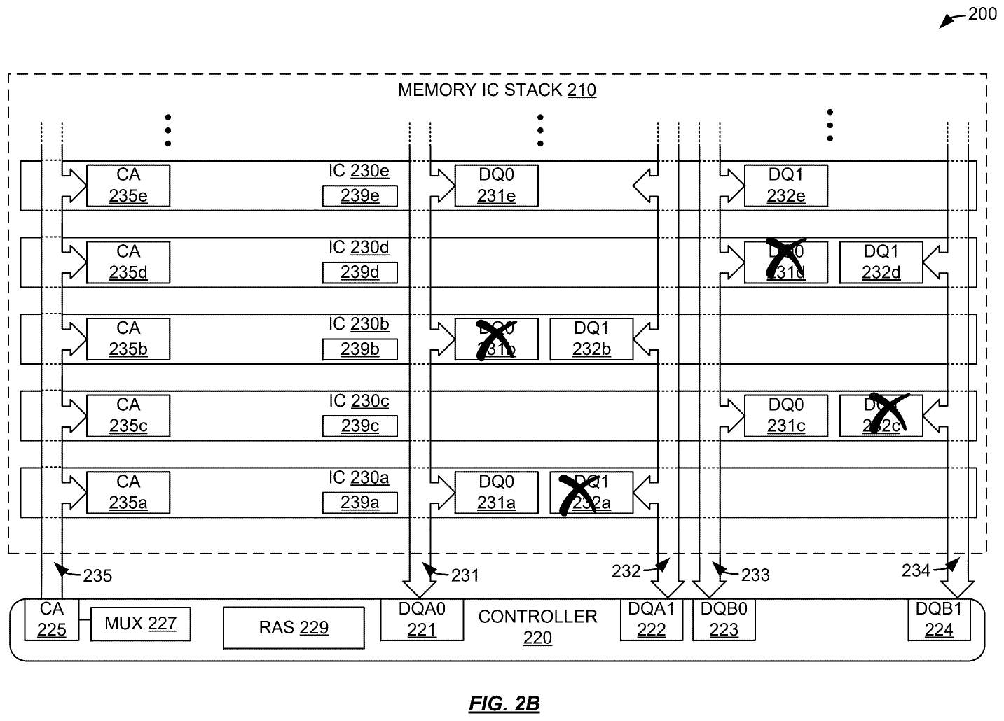

FIGS. 2A-2B are diagrams illustrating a second example memory system. In FIGS. 2A-2B, memory system 200 comprises stacked die component 210 and controller 220. Stacked die component comprises memory integrated circuit (IC) dies 230a-230e, command/address (CA) interface 235, channel “A” first bit group (DQA0) interface 221, channel “A” second bit group (DQA1) interface 222, channel “B” first bit group (DQB0) interface 223, channel “B” second bit group (DQB1) interface 224. In an embodiment, channel A first bit group and channel B first bit group correspond to the least significant bits (e.g., lower DQs or lower nibble, byte, word, etc.) of channel A and channel B, respectively. Likewise, channel A second bit group and channel B second bit group correspond to the most significant bits (e.g., upper DQs or upper nibble, byte, word, etc.) of channel A and channel B, respectively.

Each of DRAM integrated circuit die 230a-230e respectively include first bit group (DQ0) interface 231a-231e, second bit group (DQ1) interface 232a-232e, command/address (CA) interface 235a-235e, and at least one memory array 239a-239e. Controller 220 includes channel “A” first bit group (DQA0) interface 221, channel “A” second bit group (DQA1) interface 222, channel “B” first bit group (DQB0) interface 223, channel “B” second bit group (DQA1) interface 224, command/address (CA) interface 225, command multiplexer 227, and Reliability, Availability, and Serviceability (RAS) circuitry 229. In an embodiment, the DQ0 interfaces 231a-231e, DQ1 interfaces 232a-232e, DQA0 interface 221, DQA1 interface 222, DQB0 interface 223, and DQB1 interface 224 are each 8 bits (1 byte) wide.

Controller 220 and DRAM integrated circuit die 230a-230e are integrated circuit type devices, such as those commonly referred to as “chips”. A memory controller, such as controller 220, manages the flow of data going to and from memory devices. Functionality of a memory controller may be included on a single die with a microprocessor, or included as part of a more complex integrated circuit system as a block of a system on a chip (SOC). For example, a memory controller may be a northbridge chip, an application specific integrated circuit (ASIC) device, a load-reduction memory buffer, a graphics processor unit (GPU), a system-on-chip (SoC) or an integrated circuit device that includes many circuit blocks such as ones selected from graphics cores, processor cores, and MPEG encoder/decoders, etc.

Controller 220, stacked die component 210, and integrated circuit die 230a-230e may be interconnected with each other in a variety of system topologies including on a PC board (e.g., where stacked die component 210 is on a module and controller 220 is socketed to the PC board, or in “die-down” arrangement where one or more of the components are soldered to the PC board). Stacked die component 210 comprises a stack of DRAM integrated circuit die 230a-230e co-packaged together and coupled to each other and/or controller 220 via wired bonds and/or through-silicon vias (TSVs). In an embodiment, all DRAM IC dies 230a-230e in stacked die component 210 may be identical. In various embodiments, controller 220 may or may not be included in stacked die component 210 with DRAM IC dies 230a-230e.

CA interface 225 of controller 220 is operatively coupled (e.g., connected) to the CA interface 235a of DRAM IC die 230a, CA interface 235b DRAM IC die 230b, CA interface 235c of DRAM IC die 230c, CA interface 235d DRAM IC die 230d, and CA interface 235e of DRAM IC die 230e via CA interface 235 of stacked die component 210.

DQA0 interface 221 of controller 220 is operatively coupled to DQ0 interface 231a of DRAM IC die 230a, DQ0 interface 231b of DRAM IC die 230b, and DQ0 interface 231e of DRAM IC die 230e via DQA0 interface 231 of stacked die component 210. DQA1 interface 222 of controller 220 is operatively coupled to DQ1 interface 232a of DRAM IC die 230a, and DQ1 interface 232b of DRAM IC die 230b via DQA1 interface 222 of stacked die component 210. DQB0 interface 223 of controller 220 is operatively coupled to DQ0 interface 231c of DRAM IC die 230c, DQ0 interface 231d of DRAM IC die 230d, and DQ1 interface 232e of DRAM IC die 230e via DQB0 interface 233 of stacked die component 210. DQB1 interface 224 of controller 220 is operatively coupled to DQ1 interface 232c of DRAM IC die 230c, and DQ1 interface 232d of DRAM IC die 230d via DQB1 interface 234 of stacked die component 210.

In an embodiment, DQ1 interface 232a of DRAM IC die 230a, DQ0 interface 231b of DRAM IC die 230b, DQ1 interface 232c of DRAM IC die 230c, and DQ0 interface 231d of DRAM IC die 230d are disabled. DQ1 interface 232a of DRAM IC die 230a, DQ0 interface 231b of DRAM IC die 230b, DQ1 interface 232c of DRAM IC die 230c, and/or DQ0 interface 231d of DRAM IC die 230d may be disabled, for example, by controller 220 using a mode setting command (e.g., Mode Register Set command—a.k.a., MRS command) transmitted via CA interface 225. In another example, DQ1 interface 232a of DRAM IC die 230a, DQ0 interface 231b of DRAM IC die 230b, DQ1 interface 232c of DRAM IC die 230c, and/or DQ0 interface 231d of DRAM IC die 230d may be disabled by inputting (e.g., by wirebond connections to the positive and/or negative supply voltage) one or more logic values to DRAM ICs 230a-230e. Memory system 200 being configured with DQ1 interface 232a of DRAM IC die 230a, DQ0 interface 231b of DRAM IC die 230b, DQ1 interface 232c of DRAM IC die 230c, and/or DQ0 interface 231d of DRAM IC die 230d disabled is illustrated in FIG. 2B by the X's over DQ1 interface 232a of DRAM IC die 230a, DQ0 interface 231b of DRAM IC die 230b, DQ1 interface 232c of DRAM IC die 230c, and DQ0 interface 231d of DRAM IC die 230d.

In an embodiment, commands/addresses communicated via CA interface 225 directed to cause data bursts etc. to be communicated via DQA0 interface 221 and DQA1 interface 222 are time multiplexed (e.g., by command multiplexer 227) with commands/addresses communicated via CA interface 225 directed to cause data bursts etc. to be communicated via DQB0 interface 223 and DQB1 interface 224. Thus, it should be understood that the time-multiplexed commands of CA interface 225 that are directed to cause communication with DQA0 interface 221 and DQA1 interface 222, the CA interface 235a of DRAM IC die 230a, CA interface 235b of DRAM IC die 230b, CA interface 235e of DRAM IC die 230e, DQA0 interface 221 of controller 220, DQ0 interface 231a of DRAM IC die 230a, DQ1 interface 232b of DRAM IC die 230b, and DQ0 interface 231e of DRAM IC die 230e may comprise, for example, a 16 bit wide memory channel (a.k.a., channel “A”). DRAM IC die 230a may be configured, for example, (e.g., by controller 220) to communicate 8 bits of read and write data with DQA0 interface 121 of controller 220. Similarly, DRAM IC die 230b may be configured, for example, (e.g., by controller 220) to communicate 8 bits of read and write data with DQA1 interface 222 of controller 220. DRAM IC die 230e may be configured, for example, (e.g., by controller 220) to communicate 8 bits of read and write data with DQA0 interface 221 of controller 220.

In an embodiment, DRAM IC die 230e is also configured to delay processing commands received via CA interface 235e by an amount of time (e.g., clock cycles) that allows DRAM IC die 230a to complete communicating a data burst (e.g., 16 bytes) via DQA0 interface 221 before DRAM IC die 230e begins communicating a data burst (e.g., 8 bytes) via DQA0 interface 221. DRAM IC die 230b communicates a data burst (e.g., 16 bytes) via the DQA1 interface 222. This communication via the DQA0 interface 221 with DRAM IC die 230a and DRAM IC die 230e, and the communication via the DQA1 interface 222 with DRAM IC die 230b is similar to the communication illustrated in FIG. 3A. In FIGS. 3A-3C the data bursts communicated with DRAM IC die 230a is labeled with the letter “A”; the data burst communicated with DRAM IC die 230b is labeled with the letter “B”; and the data burst communicated with DRAM IC die 230e is labeled with the letter “E”.

In another embodiment, DRAM IC die 230a communicates a partial data burst (e.g., 12 bytes) and then stops communicating as DRAM IC die 230e starts communicating (e.g., 8 bytes). After DRAM IC die 230b completes communicating a data burst (e.g., 16 bytes) via DQA1 interface 222, DRAM IC die 230a restarts communicating via DQA1 interface 222 until the data burst is complete (e.g., an additional 4 bytes). By selecting the appropriately sized partial burst, DRAM IC die 230a and DRAM IC die 230e may both complete communicating at the same time (i.e., clock cycle). Example communications of a partial data burst via the DQA0 interface 221 with DRAM IC die 230a, the communication of a full data burst with DRAM IC die 230e, the communication via the DQA1 interface 222 with DRAM IC die 230b, and the remaining communication with DRAM IC die 230a via the DQA1 interface 222 is similar to the communications illustrated in FIGS. 3B-3C.

It should be understood that the time-multiplexed commands of CA interface 225 that are directed to cause communication with DQB0 interface 223 and DQB1 interface 224 of controller 220, the CA interface 235c of DRAM IC die 130c, CA interface 235d of DRAM IC die 230d, CA interface 235e of DRAM IC die 230e, DQB0 interface 223 of controller 220, DQ0 interface 231c of DRAM IC die 230c, DQ1 interface 232d of DRAM IC die 230d, and DQ1 interface 232e of DRAM IC die 230e may comprise, for example, a 16 bit wide memory channel (a.k.a., channel “B”). DRAM IC die 230c may be configured, for example, (e.g., by controller 120) to communicate 8 bits of read and write data with DQB0 interface 223 of controller 220. Similarly, DRAM IC die 230d may be configured, for example, (e.g., by controller 220) to communicate 8 bits of read and write data with DQB1 interface 224 of controller 220. DRAM IC die 230e may be configured, for example, (e.g., by controller 120) to communicate 8 bits of read and write data with DQB0 interface 223 of controller 220.

In an embodiment, DRAM IC die 230e is also configured to delay processing commands received via CA interface 235e by an amount of time (e.g., clock cycles) that allows DRAM IC die 230c to complete communicating a data burst (e.g., 16 bytes) via DQB0 interface 223 before DRAM IC die 230e begins communicating a data burst (e.g., 8 bytes) via DQB0 interface 223. DRAM IC die 230d communicates a data burst (e.g., 16 bytes) via the DQB1 interface 224. This communication via the DQB0 interface 223 with DRAM IC die 230c and DRAM IC die 230e, and the communication via the DQB1 interface 224 with DRAM IC die 230b is similar to the communication illustrated in FIG. 3A.

In another embodiment, DRAM IC die 230c communicates a partial data burst (e.g., 12 bytes) and then stops communicating as DRAM IC die 230e starts communicating (e.g., 8 bytes). After DRAM IC die 230c completes communicating a data burst (e.g., 16 bytes) via DQB1 interface 224, DRAM IC die 230c restarts communicating via DQA1 interface 224 until the data burst is complete (e.g., an additional 4 bytes). By selecting the appropriately sized partial burst, DRAM IC die 230c and DRAM IC die 230e may both complete communicating at the same time (i.e., clock cycle). Example communications of a partial data burst via the DQB0 interface 223 with DRAM IC die 230c, the communication of a full data burst with DRAM IC die 230e, the communication via the DQB1 interface 224 with DRAM IC die 230d, and the remaining communication with DRAM IC die 230c via the DQB1 interface 224 is similar to the communications illustrated in FIGS. 3B-3C.

In an embodiment, DRAM ICs 230a-230d are configured to communicate using data bursts that are 16 bytes in length and DRAM IC die 230e is configured to communicate using an 8 byte data burst. The 16 byte bursts communicated by DRAM ICs 230a-230d are used (e.g., by controller 220) to communicate data stored by DRAM ICs 230a-230d. The 8 byte bursts communicated by DRAM IC die 230e may be used to store RAS data(e.g., Reed-Solomon, parity, cyclic redundancy check, etc.), and/or metadata. FIG. 18 illustrates an example data burst (similar to the burst illustrated in FIG. 3B) with 32 data symbols (S0-S31) being communicated with (and thus stored by) DRAM IC die 230a and DRAM IC die 230b and 8 check symbols (C0-C7) being communicated with (and thus stored by) DRAM IC die 230e. FIG. 18 also illustrates which DRAM IC die 230a-230e (e.g., “die A” means DRAM IC die 230a) is communicating via which data signals. It should be understood that RAS 229 may generate check symbols (C0-C7) and check data symbols (S0-S31) and check symbols (C0-C7) illustrated in FIG. 18.

In an embodiment, RAS 229 may detect that one of DRAM ICs 230a-230d has consistent failures of two data lines (DQs). In response to this event, RAS 229 may disable the failing die, and reconfigure DRAM IC die 230e to function as the disabled die. Controller 220 may then change the RAS scheme from RS(40,32) to a system-wide error correcting code (ECC) scheme (e.g., inline ECC or any other appropriate error correcting scheme selected by system designers). DRAM IC die 230e may be configured to replace the failing die. The non-failing die in the same channel (A or B) may be reconfigured to use a different data interface (e.g., swap from using DQA0 to using DQA1) because the connections used by DRAM IC die 230e (a.k.a., the “ECC” die) are fixed. Also, the generation of any timing signals generated by DRAM IC die 230e may be disabled (see, e.g., discussion herein relating to FIGS. 9A-9B and FIGS. 10A-10B). Also, DRAM IC die 230e may be reconfigured to provide data bursts having the same length (e.g., 16 bytes) previously provided by the failing die.

FIG. 4 is a block diagrams illustrating a first example memory device. In FIG. 4, memory device 400 comprises split bank “A” 410a, split bank “B” 410b, first bit group (e.g., DQ0) interface 431, second bit group (e.g., DQ1) interface 432, command/address “A” (CAA) interface 435, command/address “A” (CAB) interface 436, first bit group (e.g., DQ0) serializer/deserializer (SERDES) 441, second bit group (e.g., DQ1) SERDES 442, bank A interconnect 445, bank B interconnect 446, and control circuitry 455. Control circuitry 456 includes mode circuitry 456.

Split bank A 410a and split bank B 410b are each organized into four bank groups BA0-BG3. Each bank group BG0-BG3 includes four banks BNK0-BNK3. SERDES 441 is illustrated as operatively coupled to first bit group interface 431. SERDES 442 is illustrated as operatively coupled to second bit group interface 432. Control circuitry 455 is illustrated as operatively coupled to first bit group SERDES 441 and second bit group SERDES 442. CAA interface 435 is operatively coupled to control circuitry 455. CAB interface 436 is operatively coupled to control circuitry 455.

In an embodiment, each of split bank A 410a and split bank B 410b may be accessed independently of each other. For example, each of split bank A 410a and split bank B 410b may prefetch a 128-bit row independently of the other split bank. In addition, each prefetch may be serialized (or deserialized) and output from either first bit group (e.g., DQ0) interface 431 or second bit group (e.g., DQ1) interface 432. This is illustrated in FIG. 4 by interconnect 445 running from a row in bank 1 of bank group 1 in split bank A 410a to both SERDES 441 and SERDES 442, and by interconnect 446 running from a row in bank 1 of bank group 1 in split bank B 410b to both SERDES 441 and SERDES 442. In an embodiment, the one of first bit group interface 431 and second bit group interface 432 used by memory device 400 is based at least in part on an MRS command (e.g., received via CAA interface 435 and/or CAB interface 436) setting mode circuitry 456.

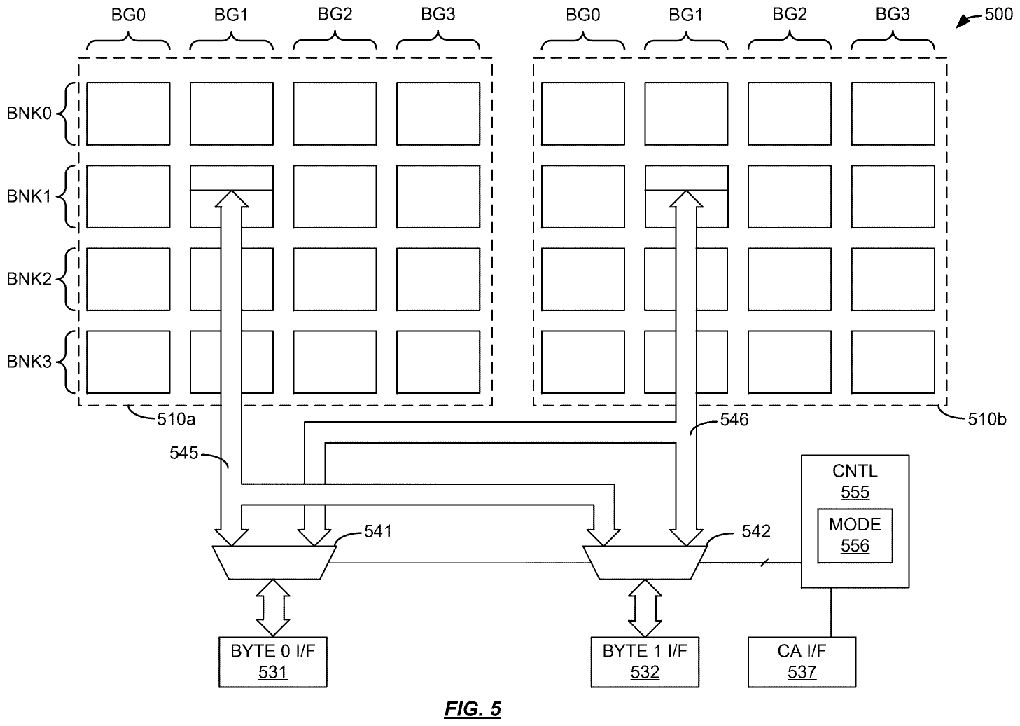

FIG. 5 is a block diagrams illustrating a second example memory device. In FIG. 5, memory device 500 comprises split bank “A” 510a, split bank “B” 510b, first bit group (e.g., DQ0) interface 531, second bit group (e.g., DQ1) interface 532, command/address (CA) interface 537, first bit group (e.g., DQ0) serializer/deserializer (SERDES) 541, second bit group (e.g., DQ1) SERDES 542, bank A interconnect 545, bank B interconnect 546, and control circuitry 555. Control circuitry 556 includes mode circuitry 556.

Split bank A 510a and split bank B 510b are each organized into four bank groups BA0-BG3. Each bank group BG0-BG3 includes four banks BNK0-BNK3. SERDES 541 is illustrated as operatively coupled to first bit group interface 531. SERDES 542 is illustrated as operatively coupled to second bit group interface 532. Control circuitry 555 is illustrated as operatively coupled to first bit group SERDES 541 and second bit group SERDES 542. CA interface 537 is operatively coupled to control circuitry 555.

In an embodiment, each of split bank A 510a and split bank B 510b may be accessed independently of each other. For example, each of split bank A 510a and split bank B 510b may prefetch a 128-bit row independently of the other split bank. In addition, each prefetch may be serialized (or deserialized) and output from either first bit group (e.g., DQ0) interface 531 or second bit group (e.g., DQ1) interface 532. This is illustrated in FIG. 5 by interconnect 545 running from a row in bank 1 of bank group 1 in split bank A 510a to both SERDES 541 and SERDES 542, and by interconnect 546 running from a row in bank 1 of bank group 1 in split bank B 510b to both SERDES 541 and SERDES 542. In an embodiment, the one of first bit group interface 531 and second bit group interface 532 used by memory device 500 is based at least in part on an MRS command (e.g., received via CA interface 537) setting mode circuitry 556.

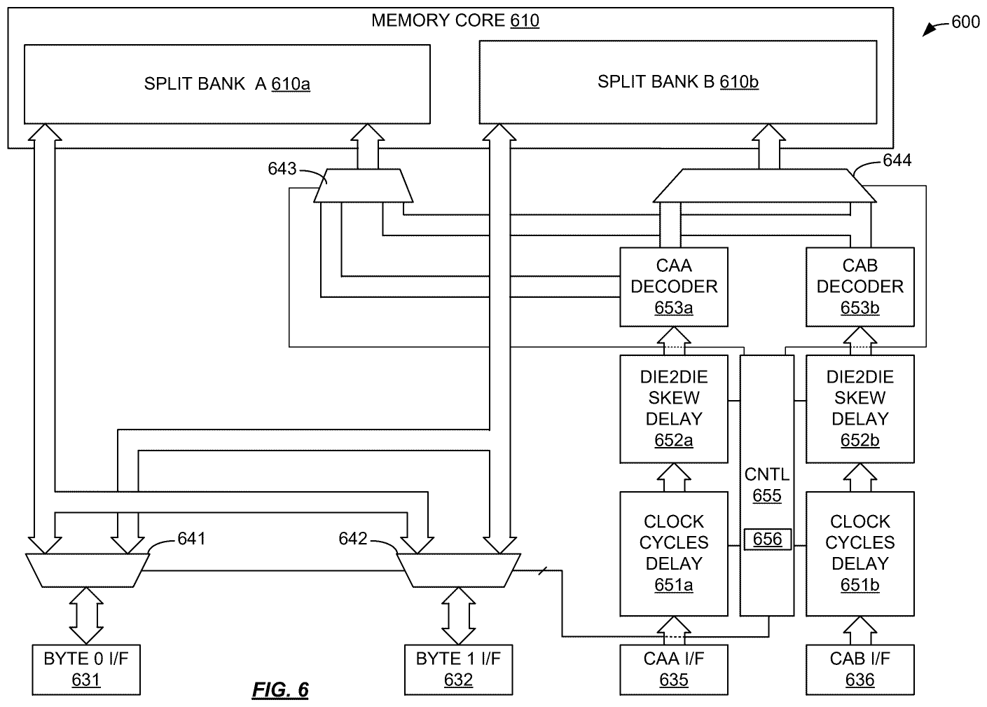

FIG. 6 is a block diagram illustrating a first example memory devices with configurable command/address processing delays. In FIG. 6, memory device 600 comprises memory core 610, first bit group (e.g., DQ0) interface 631, second bit group (e.g., DQ1) interface 632, command/address “A” (CAA) interface 635, command/address “B” (CAB) interface 636, first bit group (e.g., DQ0) serializer/deserializer (SERDES) 641, second bit group (e.g., DQ1) SERDES 642, control MUX 643, control MUX 644, clock cycles delay 651a, clock cycles delay 651b, die-to-die skew delay 652a, die-to-die skew delay 652b, command/address “A” decoder 653a, command/address “B” decoder 653b, and control circuitry 655. Memory core 610 includes split bank “A” 610a and split bank “B” 610b. Control circuitry 655 includes mode circuitry 656.

SERDES 641 is illustrated as operatively coupled to first bit group interface 631. SERDES 642 is illustrated as operatively coupled to second bit group interface 632. Control circuitry 655 is operatively coupled to SERDES 641, SERDES 642, clock cycles delay 651a, clock cycles delay 651b, die-to-die skew delay 652a, and die-to-die skew delay 652b.

CAA interface 635 is operatively coupled to clock cycles delay 651a. CAA interface 635 is operatively coupled to clock cycles delay 651a receive commands/addresses from CAA interface 635 and delay these commands/addresses by a configurable number (e.g., configured by control circuitry 655 and/or mode circuitry 656) of clock phases and/or clock cycles. The delay introduced by clock cycles delay 651 may be used to cause a device in a device stack (e.g., DRAM IC die 130e) to delay processing commands/addresses by the amount of time (e.g., clock cycles) needed for the other dies in the device stack (e.g., memory device 130a) to complete their bursts or partial bursts (e.g., as illustrated in FIG. 3A, FIG. 3B, and/or FIG. 3C) before device begins communicating in response to the command/address that was concurrently (or during the same clock cycles) received by both the device and the other devices. After delaying the commands/addresses, clock cycles delay 651a couples the commands/addresses to die-to-die skew delay 652a. In an embodiment, rather than delaying the processing of commands/addresses received via CAA interface 635, the transmission/reception of data signals via DQ0 interface 631 and DQ1 interface 632 may be delayed by the configurable amount of time (e.g., clock cycles) needed for the other dies in the device stack (e.g., memory device 130a) to complete their bursts or partial bursts.

Die-to-die skew delay 652a delays the commands/addresses by configurable times (e.g., configured by control circuitry 655 and/or mode circuitry 656) that are less than a clock cycle. The delay introduced by die-to-die skew delay 652a may be used to compensate for smaller than a clock cycle mismatches between the dies in a memory device stack. The delay introduced by die-to-die skew delay 652a may be determined by a training algorithm. After delaying the commands/addresses, die-to-die skew delay 652a couples the commands/addresses to CAA decoder 653a.

CAA decoder 653a is operatively coupled to split bank A 610a via control MUX 643 and is operatively coupled to split bank B 610b via MUX 644. CAB decoder 653b is operatively coupled to split bank A 610a via control MUX 643 and is operatively coupled to split bank B 610b via MUX 644. The selection by control MUX 643 determines which of CAA decoder 653a or CAB decoder 653b is controlling split bank A 610a. The selection by control MUX 644 determines which of CAA decoder 653a or CAB decoder 653b is controlling split bank B 610b. The selections made by control MUX 643 and control MUX 644 may be based at least in part on an MRS command (e.g., received via CAA interface 635 and/or CAB interface 636) setting mode circuitry 656.

CAA decoder 653a may be operatively coupled to split bank A 610a or split bank B 610b (e.g., by control MUX 643 and control MUX 644) to perform the commands received via CAA interface 635. In an embodiment, each of split bank A 610a and split bank B 610b may prefetch a 128-bit row independently of the other split bank. In addition, each prefetch may be serialized (or deserialized) under the control of CAA decoder 653a and output from either first bit group (e.g., DQ0) interface 631 or second bit group (e.g., DQ1) interface 632. This is illustrated in FIG. 6 by interconnect running from split bank A 610a to both SERDES 641 and SERDES 642, and by interconnect running from split bank B 610b to both SERDES 641 and SERDES 642. In an embodiment, the one of first bit group interface 631 and second bit group interface 632 used by memory device 600 is determined by an MRS command (e.g., received via CAA interface 635 and/or CAB interface 636) setting mode circuitry 656.

CAB interface 636 is operatively coupled to clock cycles delay 651b. Clock cycles delay 651b is operatively coupled to die-to-die skew delay 652b. Die-to-die skew delay 652b is operatively coupled to CAB decoder 653b. CAB decoder 653b may be operatively coupled to split bank A 610a or split bank B 610b (e.g., by control MUX 643 and control MUX 644). CAB interface 636, clock cycles delay 651b, die-to-die skew delay 652b, and CAB decoder 653b are interconnected, configured, and perform the same functions as CAA interface 635, clock cycles delay 651a, die-to-die skew delay 652a, and CAA decoder 653a, respectively. Accordingly, for the sake of brevity, the interconnection, configuration, and functioning of CAB interface 636, clock cycles delay 651b, die-to-die skew delay 652b, and CAB decoder 653b will not be discussed further herein with reference to FIG. 6. Likewise, in an embodiment, rather than delaying the processing of commands/addresses received via CAB interface 636, the transmission/reception of data signals via DQ0 interface 631 and DQ1 interface 632 may be delayed by the configurable amount of time (e.g., clock cycles) needed for the other dies in the device stack (e.g., memory device 130a) to complete their bursts or partial bursts.

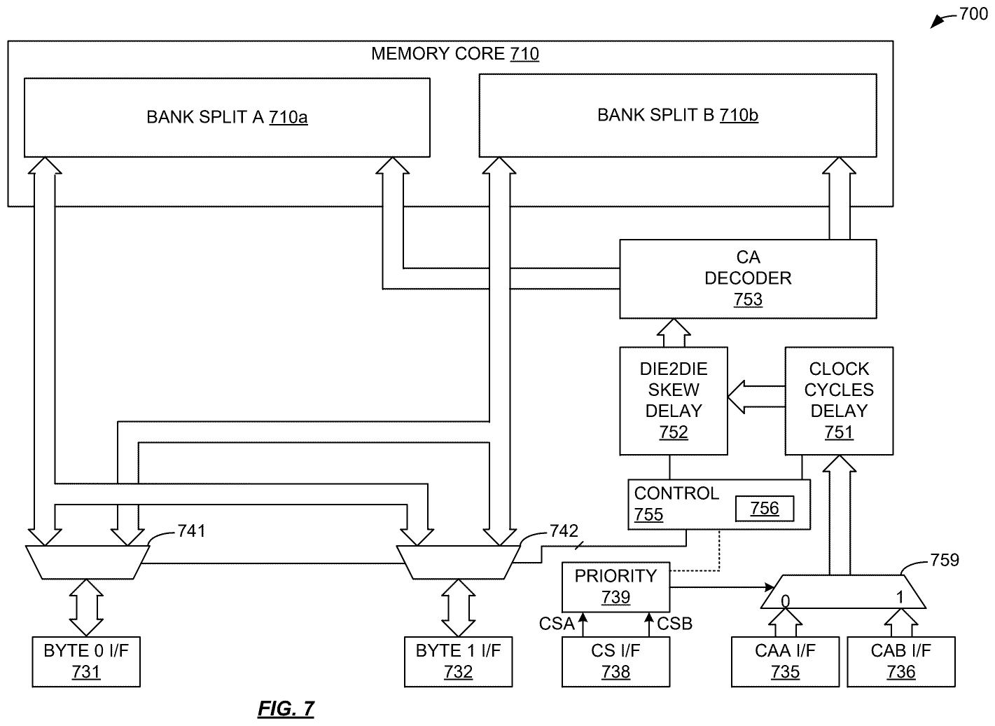

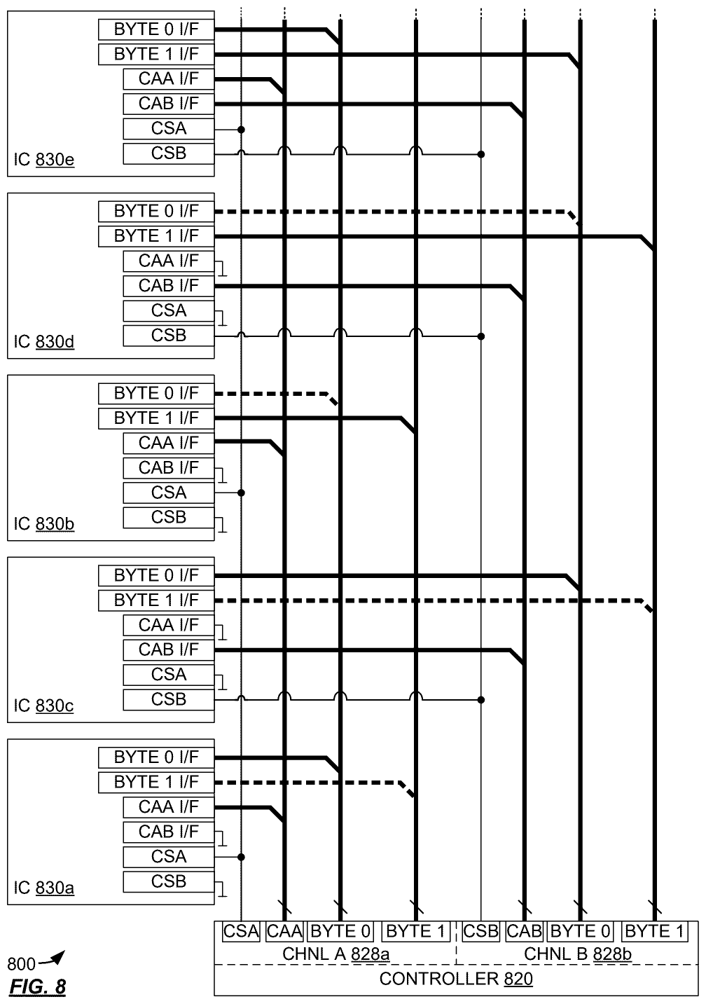

FIG. 7 is a block diagram illustrating a second example memory devices with configurable command/address processing delays. In FIG. 7, memory device 700 comprises memory core 710, first bit group (e.g., DQ0) interface 731, second bit group (e.g., DQ1) interface 732, command/address “A” (CAA) interface 735, command/address “B” (CAB) interface 736, chip select (CS) interface 738, priority encoder 739, first bit group (e.g., DQ0) serializer/deserializer (SERDES) 741, second bit group (e.g., DQ1) SERDES 742, clock cycles delay 751, die-to-die skew delay 752, command/address (CA) decoder 753, control circuitry 755, and CA bus multiplexor (MUX) 759. Memory core 710 includes split bank “A” 710a and split bank “B” 710b. Control circuitry 755 includes mode circuitry 756.

SERDES 741 is illustrated as operatively coupled to first bit group interface 731. SERDES 742 is illustrated as operatively coupled to second bit group interface 732. Control circuitry 755 is operatively coupled to SERDES 742, SERDES 742, clock cycles delay 751, and die-to-die skew delay 752. In an embodiment, priority encoder 739 may be operatively coupled to control circuitry 755. In an embodiment, priority encoder 739 may be part of control circuitry 755.

CAA interface 735 is operatively coupled the “0” input of CA MUX 759. CAB interface 736 is operatively coupled the “1” input of CA MUX 759. Chip select interface 738 is operatively coupled to priority encoder 739. In particular, chip select interface 738 receives chip select signals (e.g., from a memory controller) CSA and CSB that indicate whether signals from CAA interface 735 or signals from CAB interface 736 should be provided to clock cycles delay 751. Signals CSA and CSB from chip select interface are provided to priority encoder 739. Priority encoder 739, based on the values of CSA and CSB, provides a control signal to CA MUX 759 that determines which of the signals from CAA interface 735 or signals from CAB interface 736 are provided to clock cycles delay 751 by CA MUX 759. In an embodiment, priority encoder 739 implements the logic function given in Table 1, or its equivalent.

TABLE 1

| | | CA MUX |
|---|---|---|
| CSA | CSB | selection |
| Not asserted | Not asserted | CAA |
| Not asserted | Asserted | CAB |
| Asserted | Not asserted | CAA |
| Asserted | Asserted | CAA |

From the foregoing, it should be understood that, in an embodiment, a controller (e.g., controller 120) may use the chip select signals CSA and CSB to time multiplex the CAA and CAB buses internally to memory device 700. In another embodiment, the command/address signals may be time multiplexed at the controller and these already time multiplexed commands/addresses may only be provided to one of CAA interface 735 and CAB interface 736.

The command/address signals selected by CA MUX 759 are provided to clock cycles delay 751 to delay these commands/addresses by a configurable number (e.g., configured by control circuitry 755 and/or mode circuitry 756) of clock phases and/or clock cycles. The delay introduced by clock cycles delay 751 may be used to cause a device in a device stack (e.g., DRAM IC die 130e) to delay processing commands/addresses by the amount of time (e.g., clock cycles) needed for the other dies in the device stack (e.g., memory device 130a) to complete their bursts or partial bursts (e.g., as illustrated in FIG. 3A, FIG. 3B, and/or FIG. 3C) before device begins communicating in response to the command/address that was concurrently (or during the same clock cycles) received by both the device and the other devices. After delaying the commands/addresses, clock cycles delay 751 couples the commands/addresses to die-to-die skew delay 752. In an embodiment, rather than delaying the processing of commands/addresses received via CA MUX 759, the transmission/reception of data signals via DQ0 interface 731 and DQ1 interface 732 may be delayed by the configurable amount of time (e.g., clock cycles) needed for the other dies in the device stack (e.g., memory device 130a) to complete their bursts or partial bursts.

Die-to-die skew delay 752 delays the commands/addresses by configurable times (e.g., configured by control circuitry 755 and/or mode circuitry 756) that are less than a clock cycle. The delay introduced by die-to-die skew delay 752 may be used to compensate for smaller than a clock cycle mismatches between the dies in a memory device stack. The delay introduced by die-to-die skew delay 752 may be determined by a training algorithm. After delaying the commands/addresses, die-to-die skew delay 752 couples the commands/addresses to CA decoder 753.

CA decoder 753 is operatively coupled to split bank A 710a and split bank B 710b. CA decoder 753 is operatively coupled to split bank A 710a and split bank B 710b to perform the commands received via the selected one of CAA interface 735 or CAB interface 736. In an embodiment, each of split bank A 710a and split bank B 710b may prefetch a 128-bit row independently of the other split bank. In addition, each prefetch may be serialized (or deserialized) under the control of CA decoder 753 and output from either first bit group (e.g., DQ0) interface 731 or second bit group (e.g., DQ1) interface 732. This is illustrated in FIG. 7 by interconnect running from split bank A 710a to both SERDES 741 and SERDES 742, and by interconnect running from split bank B 710b to both SERDES 741 and SERDES 742. In an embodiment, the one of first bit group interface 731 and second bit group interface 732 used by memory device 700 is determined by an MRS command (e.g., received via CAA interface 735 and/or CAB interface 736) setting mode circuitry 756.

FIG. 8 is a block diagram illustrating example system connections for a memory device stack. In FIG. 8, memory system 800 comprises DRAM integrated circuits 830a-830e, and controller 820. Controller comprises two memory channels: memory channel “A” 828a and memory channel “B” 828b. Each of memory channel A 828a and memory channel B 828b includes a chip select signal output (CSA and CSB, respectively), command/address interface (CAA and CAB, respectively), a first bit group interface (BYTE 0), and a second bit group interface (BYTE 1). Each of DRAM integrated circuits 830a-830e has a chip select signal input CSA, chip select signal input CSB, command/address interface CAA, command/address interface CAB, a first bit group interface (BYTE 0 I/F), and a second bit group interface (BYTE 1 I/F).

The chip select signal output CSA for channel A 828a is coupled to the CSA inputs of DRAM IC 830a, DRAM IC 830b, and DRAM IC 830e. The CAA interface of memory channel A 828a is coupled to the CAA interface of DRAM IC 830a, the CAA interface of DRAM IC 830b, and the CAA interface of DRAM IC 830e. The BYTE 0 interface of channel A 828a is coupled to the BYTE 0 interface of DRAM IC 830a, and the BYTE 0 interface of DRAM IC 830e. The BYTE 1 interface of channel A 828a is coupled to the BYTE 1 interface of DRAM IC 830b.

The chip select signal output CSB for channel B 828b is coupled to the CSB inputs of DRAM IC 830c, DRAM IC 830d, and DRAM IC 830e. The CAB interface of channel B 828b is coupled to the CAB interface of DRAM IC 830c, the CAB interface of DRAM IC 830d, and the CAB interface of DRAM IC 830e. The BYTE 0 interface of channel B 828b is coupled to the BYTE 0 interface of DRAM IC 830c, and the BYTE 1 interface of DRAM IC 830e. The BYTE 1 interface of channel B 828b is coupled to the BYTE 1 interface of DRAM IC 830d.

The CSB input of DRAM IC 830a is coupled to input a non-asserted state. The CAB interface of DRAM IC 830a is unused and may be coupled to a “safe” value (e.g., all non-asserted). The CSB input of DRAM IC 830b is coupled to input a non-asserted state. The CAB interface of DRAM IC 830b is unused and may be coupled to a “safe” value (e.g., all non-asserted). The CSA input of DRAM IC 830c is coupled to input a non-asserted state. The CAA interface of DRAM IC 830c is unused and may be coupled to a “safe” value (e.g., all non-asserted). The CSA input of DRAM IC 830d is coupled to input a non-asserted state. The CAA interface of DRAM IC 830d is unused and may be coupled to a “safe” value (e.g., all non-asserted).

In an embodiment, as illustrated in FIG. 8 by the dotted lines, the BYTE 1 interface of channel A 828a may be coupled to the BYTE 1 interface of DRAM IC 830a; the BYTE 0 interface of channel A 828a may be coupled to the BYTE 0 interface of DRAM IC 830b; the BYTE 1 interface of channel B 828b may be coupled to the BYTE 1 interface of DRAM IC 830c; and/or the BYTE 0 interface of channel B 828b may be coupled to the BYTE 0 interface of DRAM IC 830d. When coupled by the dotted lines illustrated in FIG. 8, whether a particular DRAM IC 830a-830d is using which one, or both, of its BYTE 0 interface and BYTE 1 interface may be based on a mode (e.g., set by a MRS command) and/or control circuitry coupled to its respective CAA and/or CAB interface.

It should be understood that FIG. 8 illustrates a memory system 800 that is similar to memory system 100 where controller 120 (corresponding to controller 820) and memory devices 130a-130e (corresponding to memory devices 820a-820e) have separate command/address buses (i.e., CAA and CAB). In a memory system that is similar to memory system 200 where the command/address bus is time-multiplexed, the chip select signals CSA and CSB may be used to indicate whether CA is carrying commands/addresses for channel A (i.e., CAA signals) or channel B (i.e., CAB signals).

FIGS. 9A-9B are diagrams illustrating a first example data strobe provisioning for a memory device stack. In FIGS. 9A-9B, a partial memory device stack 900 is illustrated comprising DRAM IC die 930d and DRAM 9IC 930e. It should be understood that additional DRAM ICs that are identical to DRAM IC die 930d and DRAM IC die 930e that are in memory device stack 900 (but not shown in FIGS. 9A-9B, for the sake of brevity) may be interconnected and configured in the manner of DRAM IC die 930d. It should also be understood that in FIGS. 9A-9B, DRAM IC die 930d and DRAM 9IC 930e are illustrated with only a single data (DQ), single data strobe (RDQS), a single write clock (WCK). However, this was done for the sake of brevity. Multiple pads/pins, drivers, and/or receivers for multiple DQ, RDQS, and/or WCK signals are contemplated.

In FIGS. 9A-9B, DRAM IC die 930d comprises WCK receiver 961d, RDQS receiver 962d, multiplexor 963d, variable delay 964d, RDQS driver 965d, DQ synchronizer 966d, and DQ driver 967d. The input of WCK receiver 961d is operatively coupled to an external WCK signal. The output of WCK receiver 961d is provided to a first data input of MUX 963d. The input of RDQS receiver is operatively coupled to an external RDQS signal and the output of RDQS driver 965d. The output of RDQS receiver 962d is provided to a second data input of MUX 963d. The output of MUX 963d is operatively coupled to the input of variable delay 964d. The output of variable delay 964d (internal DQS signal—iDQS) is provided to the input of RDQS driver 965d and the clock (sync) input of DQ synchronizer 966d. The output of DQ synchronizer 966d is provided to the input of DQ driver 967d. The output of DQ driver 967d is provided to an external DQ signal.

DRAM IC die 930d and DRAM IC die 930e are identical in design. Thus, DRAM IC die 930e comprises WCK receiver 961e, RDQS receiver 962e, multiplexor 963e, variable delay 964e, RDQS driver 965e, DQ synchronizer 966e, and DQ driver 967e. The input of WCK receiver 961e is operatively coupled to the external WCK signal. The output of WCK receiver 961e is provided to a first data input of MUX 963e. The input of RDQS receiver is operatively coupled to the external RDQS signal and the output of RDQS driver 965e. The output of RDQS receiver 962e is provided to a second data input of MUX 963e. The output of MUX 963e is operatively coupled to the input of variable delay 964e. The output of variable delay 964e (internal DQS signal—iDQS) is provided to the input of RDQS driver 965e and the clock (sync) input of DQ synchronizer 966e. The output of DQ synchronizer 966e is provided to the input of DQ driver 967e. The output of DQ driver 967e is provided to the external DQ signal.

In an embodiment, one die in the stack (e.g., top die, die dedicated to RAS, ECC, metadata, etc.) generates the RDQS signal from a received WCK signal and distributes (provides) the generated RDQS signal to the other die in the stack. In FIGS. 9A-9B, DRAM IC die 930e is to generate RDQS and DRAM IC die 930d is to receive RDQS from DRAM IC die 930e.

FIG. 9B illustrates DRAM IC die 930e as configured (e.g., by MRS command from a controller) to generate an internal data strobe (iDQS) and an external data strobe (RDQS) based on a received WCK signal. To configure DRAM IC die 930e to generate an internal data strobe (iDQS) signal, and an external data strobe based on the internal data strobe, RDQS receiver 962e is disabled. This is illustrated by the “X” over RDQS receiver 962e in FIG. 9B. Note that this is for illustration purposes only. Another means of disabling RDQS receiver 962e would be to control MUX 963e to select the output of WCK receiver 961e.

FIG. 9B also illustrates DRAM IC die 930d as configured (e.g., by MRS command from a controller) to generate an internal data strobe signal (iDQS) based on a write clock WCK signal. To configure DRAM IC die 930d to receive the WCK signal, RDQS receiver 962d is disabled and RDQS driver 965d is disabled. This is illustrated by the “X” over RDQS receiver 962d and the “X” over RDQS driver 965d in FIG. 9B. Note that this is for illustration purposes only. Another means of disabling RDQS receiver 962d would be to control MUX 963d to select the output of WCK receiver 961d.

Thus, as can be seen in FIG. 9B, the WCK received by DRAM IC die 930e generates the internal iDQS signal that is used to synchronize DRAM IC 930e's data signals (via the clock input to DQ synchronizer 966e) and is also used to transmit an external data strobe (RDQS) to a controller. Because there is likely to be different signal conductor length between dies in the stack, training of variable delay 964e and/or variable delay 964d (and corresponding variable delays in the other die of the stack) may be used to compensate for die-to-die skew of the RDQS signal internal to and provided by DRAM IC 960e.

FIGS. 10A-10B are diagrams illustrating a second example data strobe provisioning for a memory device stack. In FIGS. 10A-10B, a partial memory device stack 1000 is illustrated comprising DRAM IC die 1030d and DRAM 10IC 1030e. It should be understood that additional DRAM ICs that are identical to DRAM IC die 1030d and DRAM IC die 1030e that are in memory device stack 1000 (but not shown in FIGS. 10A-10B, for the sake of brevity) may be interconnected and configured in the manner of DRAM IC die 1030d. It should also be understood that in FIGS. 10A-10B, DRAM IC die 1030d and DRAM 10IC 1030e are illustrated with only a single data (DQ), single data strobe (RDQS), a single write clock (WCK). However, this was done for the sake of brevity. Multiple pads/pins, drivers, and/or receivers for multiple DQ, RDQS, and/or WCK signals are contemplated.

In FIGS. 10A-10B, DRAM IC die 1030d comprises WCK receiver 1061d, RDQS receiver 1062d, multiplexor 1063d, variable delay 1064d, RDQS driver 1065d, DQ synchronizer 1066d, and DQ driver 1067d. The input of WCK receiver 1061d is operatively coupled to an external WCK signal. The output of WCK receiver 1061d is provided to a first data input of MUX 1063d. The input of RDQS receiver is operatively coupled to an external RDQS signal and the output of RDQS driver 1065d. The output of RDQS receiver 1062d is provided to a second data input of MUX 1063d. The output of MUX 1063d (internal DQS signal—iDQS) is operatively coupled to the input of variable delay 1064d and the input of RDQS driver 1065d. The output of variable delay 1064d is provided the clock (sync) input of DQ synchronizer 1066d. The output of DQ synchronizer 1066d is provided to the input of DQ driver 1067d. The output of DQ driver 1067d is provided to an external DQ signal.

DRAM IC die 1030d and DRAM IC die 1030e are identical in design. Thus, DRAM IC die 1030e comprises WCK receiver 1061e, RDQS receiver 1062e, multiplexor 1063e, variable delay 1064e, RDQS driver 1065e, DQ synchronizer 1066e, and DQ driver 1067e. The input of WCK receiver 1061e is operatively coupled to the external WCK signal. The output of WCK receiver 1061e is provided to a first data input of MUX 1063e. The input of RDQS receiver is operatively coupled to the external RDQS signal and the output of RDQS driver 1065e. The output of RDQS receiver 1062e is provided to a second data input of MUX 1063e. The output of MUX 1063e (internal DQS signal—iDQS) is operatively coupled to the input of variable delay 1064e and the input of RDQS driver 1065d. The output of variable delay 1064e is provided the clock (sync) input of DQ synchronizer 1066e. The output of DQ synchronizer 1066e is provided to the input of DQ driver 1067e. The output of DQ driver 1067e is provided to the external DQ signal.

In an embodiment, one die in the stack (e.g., top die, die dedicated to RAS, ECC, metadata, etc.) generates the RDQS signal from a received WCK signal and distributes (provides) the generated RDQS signal to the other die in the stack. In FIGS. 10A-10B, DRAM IC die 1030e is to generate RDQS and DRAM IC die 1030d is to receive RDQS from DRAM IC die 1030e.

FIG. 10B illustrates DRAM IC die 1030e as configured (e.g., by MRS command from a controller) to provide RDQS based on a received WCK signal. To configure DRAM IC die 1030e to provide the RDQS signal, RDQS receiver 1062e is disabled. This is illustrated by the “X” over RDQS receiver 1062e in FIG. 10B. Note that this is for illustration purposes only. Another means of disabling RDQS receiver 1062e would be to control MUX 1063e to select the output of WCK receiver 1061e.

FIG. 10B also illustrates DRAM IC die 1030d as configured (e.g., by MRS command from a controller) to receive RDQS from DRAM IC die 1030e. To configure DRAM IC die 1030d to receive the RDQS signal, RDQS driver 1065d is disabled and WCK receiver 1061d is disabled. This is illustrated by the “X” over RDQS driver 1065d and the “X” over WCK receiver 1061d in FIG. 10B. Note that this is for illustration purposes only. Another means of disabling WCK receiver 1061d would be to control MUX 1063d to select the output of RDQS receiver 1061d.

Thus, as can be seen in FIG. 10B, the WCK received by DRAM IC die 1030e generates the internal iDQS signal that is used to synchronize DRAM IC 10030e's data signals (via variable delay 1064e and the clock input to DQ synchronizer 1066e) and is also used to transmit an external data strobe (RDQS) to DRAM IC die 1030d (via RDQS driver 1065e). Because there likely to be different signal conductor length between dies in the stack, training of variable delay 1064e and/or variable delay 1064d (and corresponding variable delays in the other die of the stack) may be used to compensate for die-to-die skew of the RDQS signal internal to and provided by DRAM IC 1060e. Memory write operations to a first memory device (e.g. DRAM IC die 1030d), second memory device (e.g., DRAM IC die 1030e), and/or a third memory device is performed similarly to memory read operation and the write operation and is timed by WCK

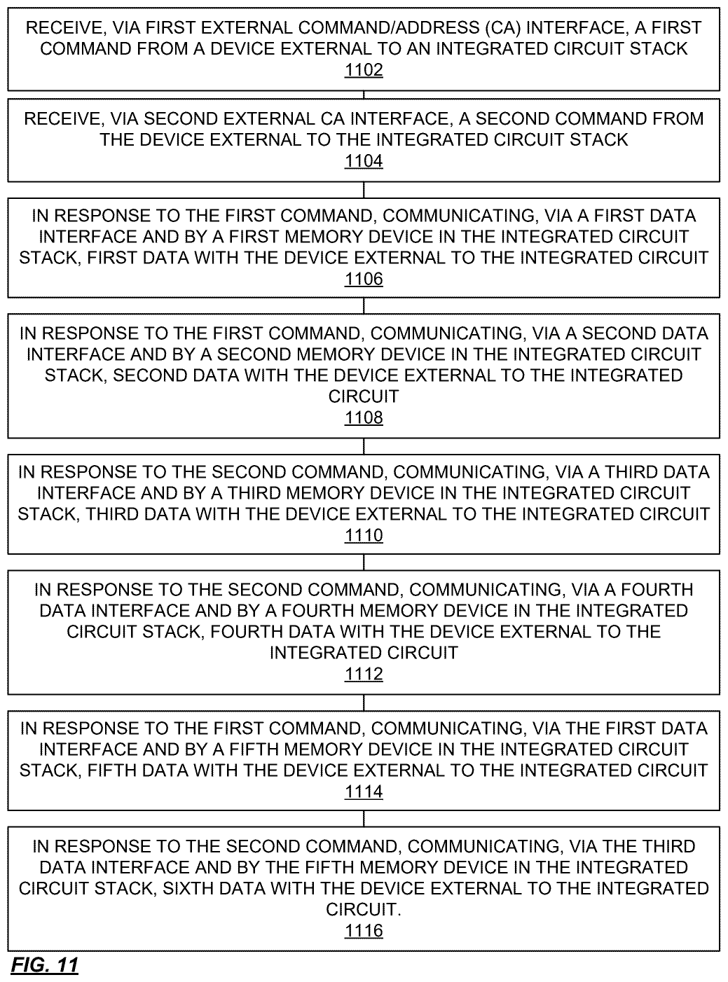

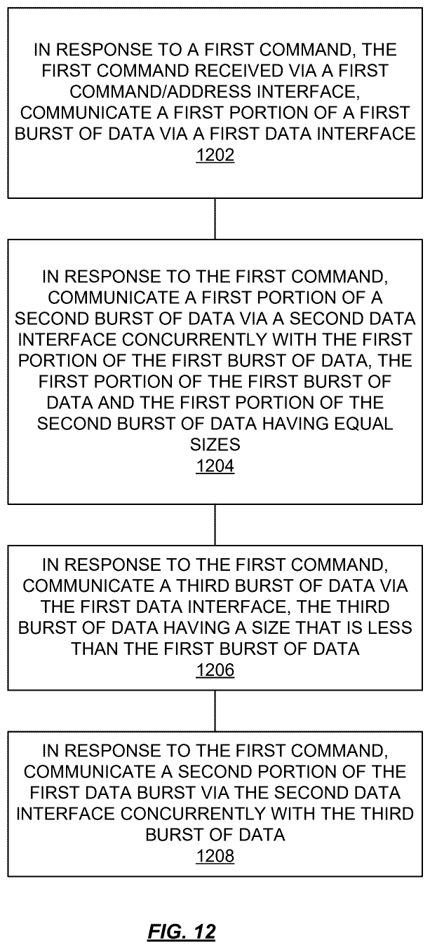

FIG. 11 is a flowchart illustrating a method of operating an integrated circuit stack. One or more steps illustrated in FIG. 11 may be performed by, for example, system 100, system 200, memory device 400, memory device 500, memory device 600, memory device 700, system 800, memory device stack 900, memory device stack 1000, system 1900, and/or their components. Via a first external command/address (CA) interface, a first command from a device external to an integrated circuit stack is received (1102). For example, stacked die component 110 may receive a first command via CAA interface 135. Via a second external command/address (CA) interface, a second command from the device external to the integrated circuit stack is received (1104). For example, stacked die component 110 may receive a second command via CAB interface 136.

In response to the first command, via a first data interface and by a first memory device in the integrated circuit stack, first data is communicated with the device external to the integrated circuit stack (1106). For example, DRAM IC die 130a may communicate a 16 byte long data burst, via DQA0 interface 131a, DQA0 interface 131, and DQA0 interface 121, with controller 120. In response to the first command, via a second data interface and by a second memory device in the integrated circuit stack, second data is communicated with the device external to the integrated circuit stack (1108). For example, DRAM IC die 130b may communicate a 16 byte long data burst, via DQA1 interface 132a, DQA1 interface 132, and DQA1 interface 122, with controller 120.

In response to the second command, via a third data interface and by a third memory device in the integrated circuit stack, third data is communicated with the device external to the integrated circuit stack (1110). For example, DRAM IC die 130c may communicate a 16 byte long data burst, via DQB0 interface 133a, DQB0 interface 133, and DQB0 interface 123, with controller 120. In response to the second command, via a fourth data interface and by a fourth memory device in the integrated circuit stack, fourth data is communicated with the device external to the integrated circuit stack (1112). For example, DRAM IC die 130d may communicate a 16 byte long data burst, via DQB1 interface 134a, DQB1 interface 134, and DQB1 interface 124, with controller 120.

In response to the first command, via the first data interface and by a fifth memory device in the integrated circuit stack, fifth data is communicated with the device external to the integrated circuit stack (1114). For example, after DRAM IC die 130e has completed its data burst via DQA0 interface 131 and DQA0 interface 121, DRAM IC die 130e may communicate an 8 byte long data burst, via DQA0 interface 131e, DQA0 interface 131, and DQA0 interface 121, with controller 120. In response to the second command, via the third data interface and by the fifth memory device in the integrated circuit stack, sixth data is communicated with the device external to the integrated circuit stack (1116). For example, after DRAM IC die 130c has completed its data burst via DQB0 interface 1331 and DQB0 interface 123, DRAM IC die 130e may communicate an 8 byte long data burst, via DQB0 interface 133e, DQB0 interface 133, and DQB0 interface 123, with controller 120.

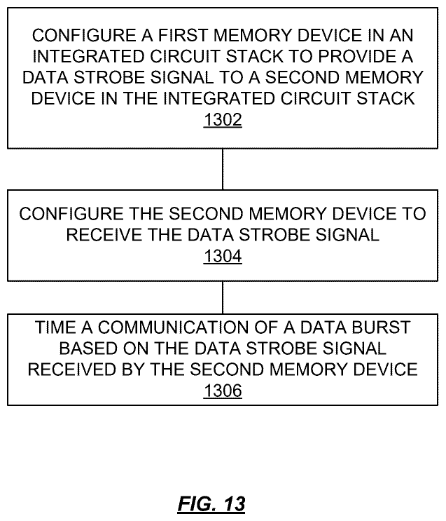

FIG. 12 is a flowchart illustrating a method of communicating data bursts from multiple memory devices in a memory device stack. One or more steps illustrated in FIG. 12 may be performed by, for example, system 100, system 200, memory device 400, memory device 500, memory device 600, memory device 700, system 800, memory device stack 900, memory device stack 1000, system 1900, and/or their components. In response to a first command, the first command received via a first command/address interface, a first portion of a first burst of data is communicated via a first data interface (1202). For example, in response to a first command to communicate a 16 byte data burst received via CAA interface 135, DRAM IC die 130a may communicate a first 12 bytes of the 16 byte data burst via DQA0 interface 131 (see e.g., FIG. 3B).

In response to the first command, a first portion of a second burst of data is communicated via a second data interface concurrently with the first portion of the first burst of data, the first portion of the first burst of data and the first portion of the second burst of data having equal sizes (1204). For example, in response to the first command to communicate a 16 byte data burst received via CAA interface 135, DRAM IC die 130b may communicate a first 12 bytes of the 16 byte data burst via DQA1 interface 132 (see e.g., FIG. 3B). In response to the first command, a third burst of data is communicated via the first data interface, the third bust of data having a size that is less than the first burst of data (1206). For example, in response to the first command, DRAM IC die 130e may communicate an eight byte data burst via DQA0 interface 131 (see e.g., FIG. 3B). In response to the first command, a second portion of the first data burst is communicated via the second data interface concurrently with the third burst of data (1208). For example, in response to the first command to communicate a 16 byte data burst received via CAA interface 135, DRAM IC die 130a may communicate the remaining 4 bytes of the 16 byte data burst via DQA1 interface 132 while DRAM IC die 130e is communicating at least a portion of its eight byte data burst via DQA0 interface 131 (see e.g., FIG. 3B).

FIG. 13 is a flowchart illustrating a method of providing data strobes for a data burst. One or more steps illustrated in FIG. 13 may be performed by, for example, system 100, system 200, memory device 400, memory device 500, memory device 600, memory device 700, system 800, memory device stack 900, memory device stack 1000, system 1900, and/or their components. A first memory device in an integrated circuit stack is configured to provide a data strobe signal to a second memory device in the integrated circuit stack (1302). For example, DRAM IC die 1030e of memory device stack 1000 may be configured (e.g., by a controller and by disabling RDQS receiver 1062e) to provide an external data strobe signal (RDQS) to other memory devices (e.g., DRAM IC die 1030d) stacked with DRAM IC die 1030e in memory device stack 1000.

A second memory device is configured to receive the data strobe signal (1304). For example, DRAM IC die 1030d of memory device stack 1000 may be configured (e.g., by the controller and by disabling RDQS driver 1065d and by disabling WCK receiver 1061d) to receive the external data strobe signal (RDQS) for DRAM IC die 1030e. A communication of a data burst is timed based on the data strobe signal received by the second memory device (1306). For example, DRAM IC die 1030d of memory device stack 1000 may use the received RDQS signal to synchronize (e.g., by DQ synchronizer 1066d) the transmission of a data burst transmitted using at least one DQ signal pin.

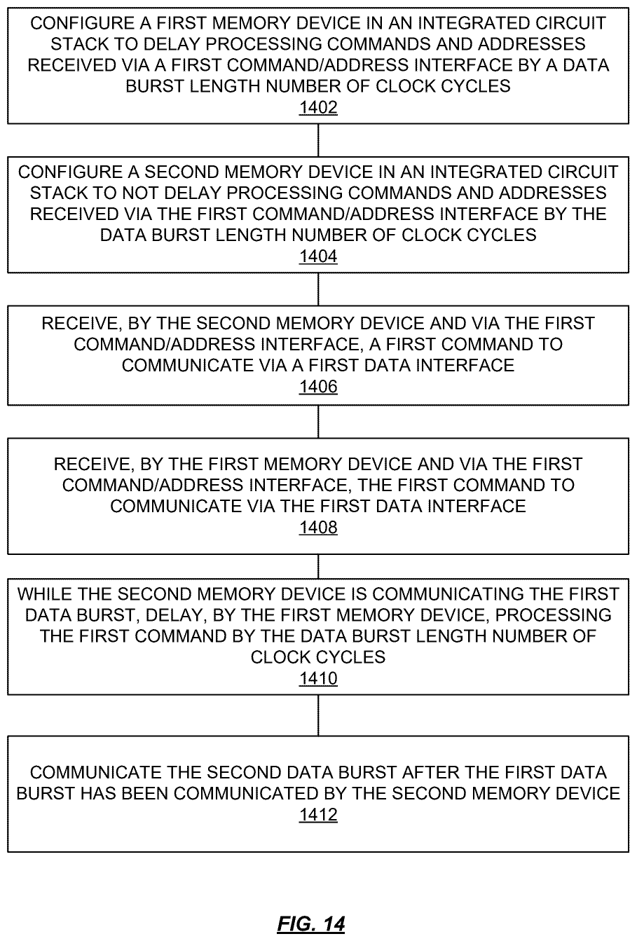

FIG. 14 is a flowchart illustrating a first example method of time multiplexing accesses to multiple memory devices in a memory device stack. One or more steps illustrated in FIG. 14 may be performed by, for example, system 100, system 200, memory device 400, memory device 500, memory device 600, memory device 700, system 800, memory device stack 900, memory device stack 1000, system 1900, and/or their components. A first memory device in an integrated circuit stack is configured to delay processing commands and addresses received via a first command/address interface by a data burst length number of clock cycles (1402). For example, DRAM IC die 130e may be configured to delay (e.g., by clock cycles delay 651a or its equivalent) processing commands and address received via CAA interface 135 from controller 120 by a data burst length number of clock cycles (e.g., 16 clock cycles or 16 clock phases).

A second memory device in the integrated circuit stack is configured to not delay processing commands and addresses received via the first command/address interface by the data burst length number of clock cycles (1404). For example, DRAM IC die 130a may be configured to not delay (e.g., by clock cycles delay 651a or its equivalent) processing commands and address received via CAA interface 135 from controller 120. By the second memory device and via the first command/address interface, a first command to communicate via a first data interface is received (1406). For example, DRAM IC die 130a may receive, via CAA interface 135, a first command to communicate a first data burst (e.g., 16 bytes) via DQA0 interface 131.

By the first memory device and via the first command/address interface, the first command to communicate via the first data interface is received (1408). For example, DRAM IC die 130e may receive, via CAA interface 135, a first command to communicate a first data burst (e.g., 16 bytes) via DQA0 interface 131. While the second memory device is communicating the first data burst and by the first memory device, processing the first command is delayed by the data burst length number of clock cycles (1410). For example, while DRAM IC die 130a is communicating via CAA interface 135, DRAM IC die 130e may delay (e.g., by clock cycles delay 651a or its equivalent) processing the first command it received via CAA interface 135 concurrently with DRAM IC die 130a. after the first data burst has been communicated by the second memory device, the second data burst is communicated by the first memory device (1412). For example, due to the delay by DRAM IC die 130e in processing the first command, DRAM IC die 130e may communicate the second data burst after the first data burst has been communicated by DRAM IC die 130a (see, e.g., FIG. 3A).

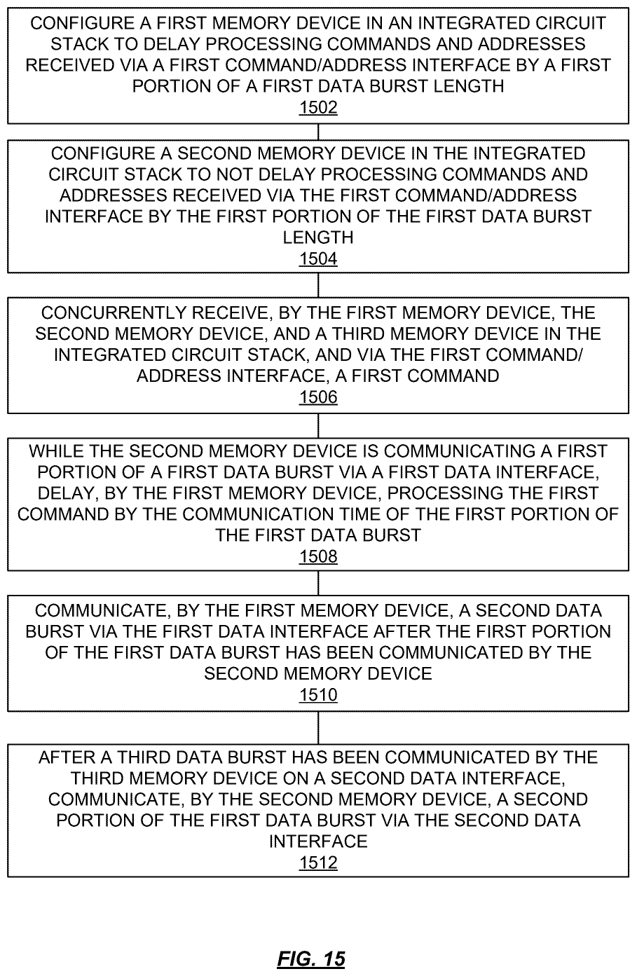

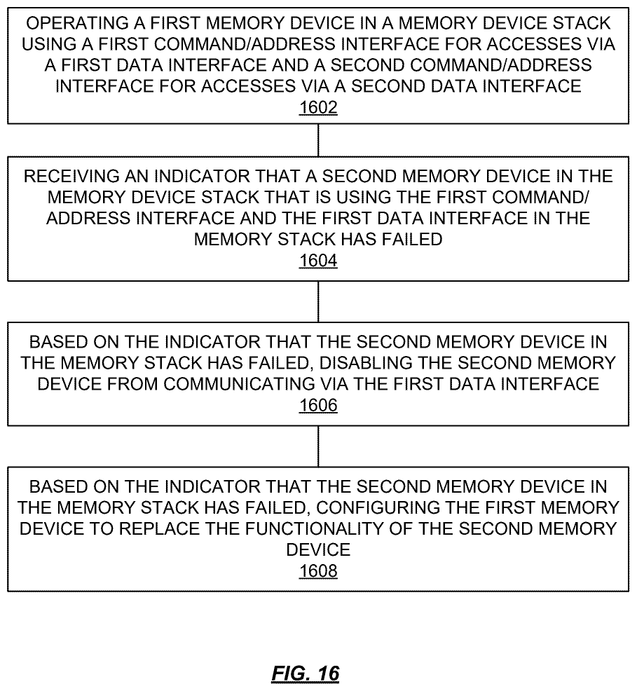

FIG. 15 is a flowchart illustrating a second example method of time multiplexing accesses to multiple memory devices in a memory device stack. One or more steps illustrated in FIG. 15 may be performed by, for example, system 100, system 200, memory device 400, memory device 500, memory device 600, memory device 700, system 800, memory device stack 900, memory device stack 1000, system 1900, and/or their components. A first memory device in an integrated circuit stack is configured to delay processing commands and addresses received via a first command/address interface by a first portion of a first data burst length (1502). For example, DRAM IC die 130e may be configured to delay processing commands and address received via CAA interface 135 from controller 120 by a portion of a data burst length number (e.g., 12 clock cycles or phases for a data bust length of 16 clock cycles or phases, respectively—see, e.g., FIG. 3B) of clock cycles.

A second memory device in the integrated circuit stack is configured to not delay processing commands and addresses received via a first command/address interface by the first portion of a first data burst length (1504). For example, DRAM IC die 130a may be configured not to delay processing commands and address received via CAA interface 135 from controller 120.

By the first memory device, the second memory device, and a third memory device in the integrated circuit stack, a first command is received via the first command/address interface (1506). For example, DRAM IC die 130e, DRAM IC die 130a, and DRAM IC die 130b may concurrently receive, via CAA interface 135, a first command to access the memory array 139e, memory array 139a, and memory array 139b, respectively. While the second memory device is communicating a first portion of a first data burst via a first data interface, processing of the first command by the first memory device is delayed by a communication time of the first portion of the first data burst (1508). For example, while DRAM IC die 130a is communicating a first portion (e.g., 12 bytes) via DQA0 interface 131, DRAM IC die 130e may delay processing the first command it received via CAA interface 135 concurrently with DRAM IC die 130a by the amount of time (clock cycles) it takes for DRAM IC die 130a to communicate the first portion of the first data burst.

By the first memory device, a second data burst is communicated via the first data interface after the first portion of the first data burst has been communicated by the second memory device (1510). For example, due to the delay by DRAM IC die 130e in processing the first command, DRAM IC die 130e may communicate a second data burst (e.g., 8 bytes) after the first portion of the first data burst (e.g., 12 bytes) has been communicated by DRAM IC die 130a (see, e.g., FIG. 3B). After a third data burst has been communicated by the third memory device on a second data interface, a second portion of the first data burst is communicated by the second memory device via the second data interface (1512). For example, after DRAM IC die 130b has communicated a data burst via DQA1 interface 132 in response to the first command, DRAM IC die 130a may communicate the remaining portion of the first data burst via DQA1 interface 132.

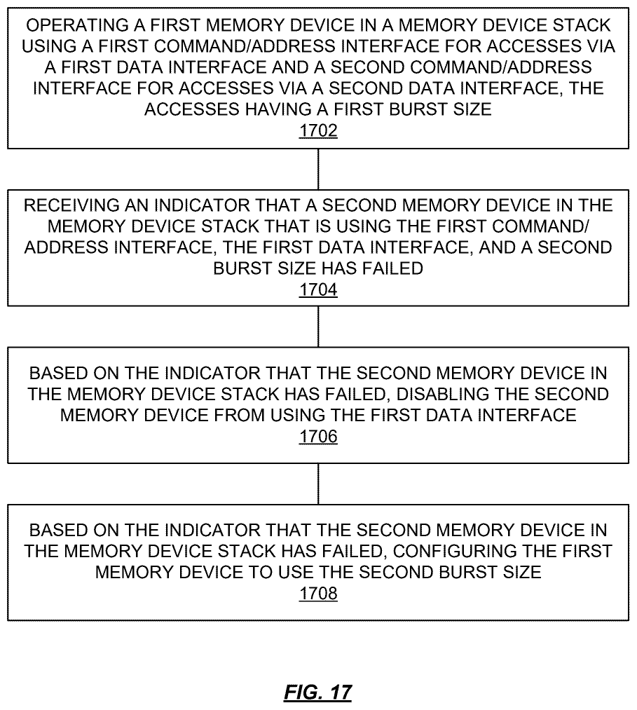

FIG. 16 is a flowchart illustrating a first example method of replacing the functionality of a failed memory device in a memory device stack. One or more steps illustrated in FIG. 16 may be performed by, for example, system 100, system 200, memory device 400, memory device 500, memory device 600, memory device 700, system 800, memory device stack 900, memory device stack 1000, system 1900, and/or their components. A first memory device in a memory device stack is operated using a first command/address interface for accesses via a first data interface and a second command/address interface for access via a second data interface (1602). For example, DRAM IC die 130e in stacked die component 110 may be operated while configured and connected to communicate data via DQA0 interface 131 of stacked die component 110 in response to commands received via CAA interface 135, and configured and connected to communicate data via DQA1 interface 132 of stacked die component 110 in response to commands received via CAB interface 136e.

An indicator that a second memory device in the memory device stack that is using the first command/address interface and the first data interface has failed is received (1604). For example, RAS circuitry 129 may detect, and indicate to controller 120 (and/or the host system) that two or more data signals of DQA0 interface 131a of DRAM IC die 130a have failed or are otherwise exhibiting failing behavior. Based on the indicator that the second memory device in the memory stack has failed, the second memory device is disabled from communicating via the first data interface (1606). For example, controller 120 (and/or the host system) may, in response to RAS circuitry 129 indicating that DRAM IC130a has failed or is otherwise exhibiting failing behavior, disable DQA0 interface 131a of DRAM IC die 130a. Based on the indicator that the second memory device in the memory stack has failed, the first memory device is configured to replace the functionality of the second memory device (1608). For example, controller 120 (and/or the host system) may, in response to RAS circuitry 129 indicating that DRAM IC130a has failed or is otherwise exhibiting failing behavior, configure DRAM IC die 130e to replace the storage and communication functions previously provided by DRAM IC die 130a.

FIG. 17 is a flowchart illustrating a first example method of replacing the functionality of a failed memory device in a memory device stack. One or more steps illustrated in FIG. 17 may be performed by, for example, system 100, system 200, memory device 400, memory device 500, memory device 600, memory device 700, system 800, memory device stack 900, memory device stack 1000, system 1900, and/or their components. A first memory device in a memory device stack is operated using a first command/address interface for accesses via a first data interface and a second command/address interface for access via a second data interface where the accesses have a first burst size (1702). For example, DRAM IC die 130e in stacked die component 110 may be operated while configured and connected to communicate data via DQA0 interface 131 of stacked die component 110 in response to commands received via CAA interface 135 using an 8 byte burst length, and configured and connected to communicate data via DQA1 interface 132 of stacked die component 110 in response to commands received via CAB interface 136e using an 8 byte burst length.

An indicator that a second memory device in the memory device stack that is using the first command/address interface and the first data interface using a second burst size has failed is received (1704). For example, RAS circuitry 129 may detect, and indicate to controller 120 (and/or the host system) that two or more data signals of DQA0 interface 131a of DRAM IC die 130a, which is using a 16 byte burst length, have failed or are otherwise exhibiting failing behavior. Based on the indicator that the second memory device in the memory stack has failed, the second memory device is disabled from communicating via the first data interface (1706). For example, controller 120 (and/or the host system) may, in response to RAS circuitry 129 indicating that DRAM IC130a has failed or is otherwise exhibiting failing behavior, disable DQA0 interface 131a of DRAM IC die 130a. Based on the indicator that the second memory device in the memory stack has failed, the first memory device is configured to use the second burst size (1708). For example, controller 120 (and/or the host system) may, in response to RAS circuitry 129 indicating that DRAM IC130a has failed or is otherwise exhibiting failing behavior, configure DRAM IC die 130e to use a 16 byte burst length.

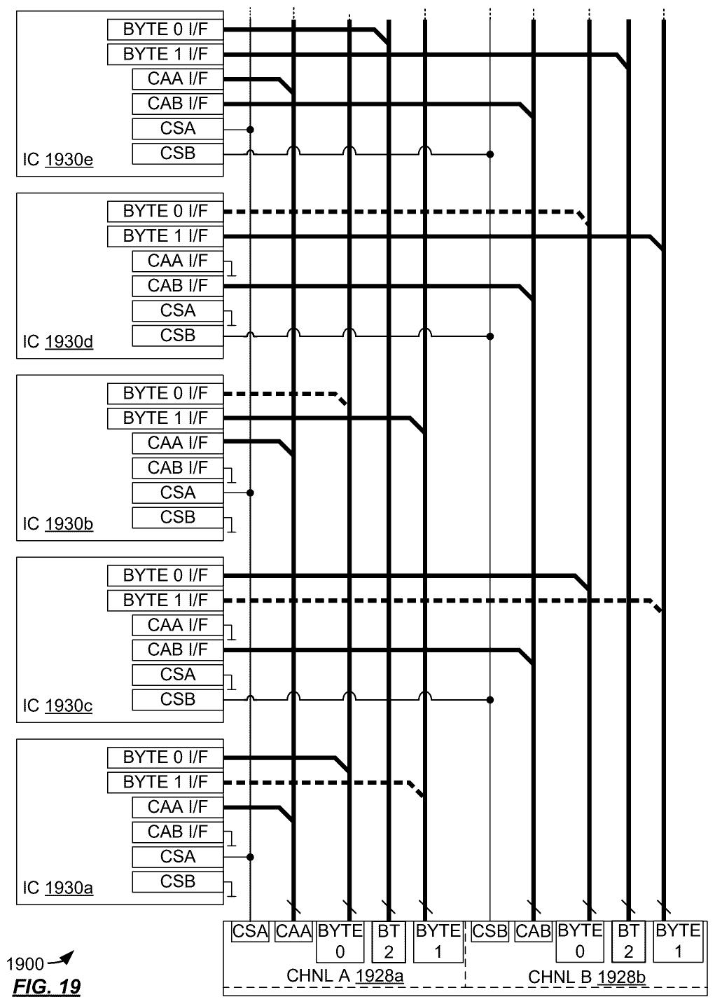

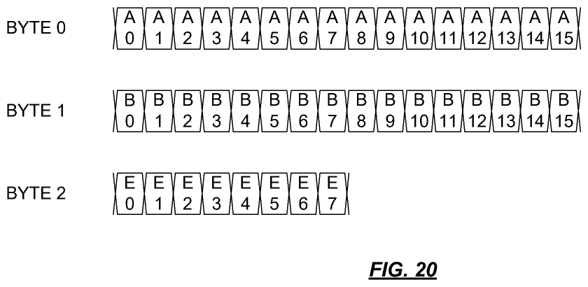

FIG. 19 is a block diagram illustrating example system connections for a memory device stack. In FIG. 19, memory system 1900 comprises DRAM integrated circuits 1930a-1930e, and controller 1920. Controller comprises two memory channels: memory channel “A” 1928a and memory channel “B” 1928b. Each of memory channel A 1928a and memory channel B 1928b includes a chip select signal output (CSA and CSB, respectively), command/address interface (CAA and CAB, respectively), a first bit group interface (BYTE 0), a second bit group interface (BYTE 1), and a supplemental data byte interface (BYTE 2). Each of DRAM integrated circuits 1930a-830e has a chip select signal input CSA, chip select signal input CSB, command/address interface CAA, command/address interface CAB, a first bit group interface (BYTE 0 I/F), and a second bit group interface (BYTE 1 I/F).

The chip select signal output CSA for channel A 1928a is coupled to the CSA inputs of DRAM IC 1930a, DRAM IC 1930b, and DRAM IC 1930e. The CAA interface of memory channel A 1928a is coupled to the CAA interface of DRAM IC 1930a, the CAA interface of DRAM IC 1930b, and the CAA interface of DRAM IC 1930e. The BYTE 0 interface of channel A 1928a is coupled to the BYTE 0 interface of DRAM IC 1930a. The BYTE 1 interface of channel A 1928a is coupled to the BYTE 1 interface of DRAM IC 1930b. The BYTE 2 interface of channel A 1928a is coupled to the BYTE 0 interface of DRAM IC 1930e.

The chip select signal output CSB for channel B 1928b is coupled to the CSB inputs of DRAM IC 1930c, DRAM IC 1930d, and DRAM IC 1930e. The CAB interface of channel B 1928b is coupled to the CAB interface of DRAM IC 1930c, the CAB interface of DRAM IC 1930d, and the CAB interface of DRAM IC 1930e. The BYTE 0 interface of channel B 1928b is coupled to the BYTE 0 interface of DRAM IC 1930c. The BYTE 1 interface of channel B 1928b is coupled to the BYTE 1 interface of DRAM IC 1930d. The BYTE 2 interface of channel B 1928b is coupled to the BYTE 1 interface of DRAM IC 1930e.

The CSB input of DRAM IC 1930a is coupled to input a non-asserted state. The CAB interface of DRAM IC 1930a is unused and may be coupled to a “safe” value (e.g., all non-asserted). The CSB input of DRAM IC 1930b is coupled to input a non-asserted state. The CAB interface of DRAM IC 1930b is unused and may be coupled to a “safe” value (e.g., all non-asserted). The CSA input of DRAM IC 1930c is coupled to input a non-asserted state. The CAA interface of DRAM IC 1930c is unused and may be coupled to a “safe” value (e.g., all non-asserted). The CSA input of DRAM IC 1930d is coupled to input a non-asserted state. The CAA interface of DRAM IC 1930d is unused and may be coupled to a “safe” value (e.g., all non-asserted).

In an embodiment, as illustrated in FIG. 19 by the dotted lines, the BYTE 1 interface of channel A 1928a may be coupled to the BYTE 1 interface of DRAM IC 1930a; the BYTE 0 interface of channel A 1928a may be coupled to the BYTE 0 interface of DRAM IC 1930b; the BYTE 1 interface of channel B 1928b may be coupled to the BYTE 1 interface of DRAM IC 1930c; and/or the BYTE 0 interface of channel B 1928b may be coupled to the BYTE 0 interface of DRAM IC 1930d. When coupled by the dotted lines illustrated in FIG. 19, whether a particular DRAM IC 1930a-1930d is using which one, or both, of its BYTE 0 interface and BYTE 1 interface may be based on a mode (e.g., set by a MRS command) and/or control circuitry coupled to its respective CAA and/or CAB interface.

It should be understood that FIG. 19 illustrates a memory system 1900 that is similar to memory system 100 where controller 120 (corresponding to controller 1920) and memory devices 130a-130e (corresponding to memory devices 1920a-820e) have separate command/address buses (i.e., CAA and CAB). In a memory system that is similar to memory system 200 where the command/address bus is time-multiplexed, the chip select signals CSA and CSB may be used to indicate whether CA is carrying commands/addresses for channel A (i.e., CAA signals) or channel B (i.e., CAB signals).

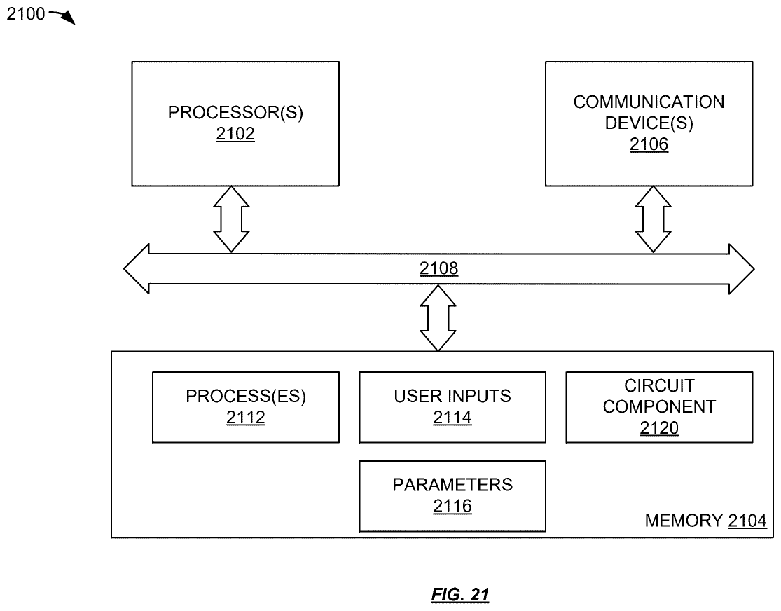

Is should also be understood from FIG. 19 that memory system 1900 may communicate data with DRAM IC 1930e via additional signal lines (e.g., when compared to system 100, system 200, system 800 etc.) rather than extending the length of bursts with the data to/from DRAM IC 1930e. An MRS command or other configuration information may be used to configure DRAM IC 1930e to communicate using timing for communication that is concurrent two or more of DRAM ICs 1930a-1930d. FIG. 20 is a diagram illustrating example memory device stack data bursts. The example data bursts illustrated in FIG. 20 may be bursts used by, for example, channel A 1928a and/or channel B 1928b.

The methods, systems and devices described above may be implemented in computer systems, or stored by computer systems. The methods described above may also be stored on a non-transitory computer readable medium. Devices, circuits, and systems described herein may be implemented using computer-aided design tools available in the art, and embodied by computer-readable files containing software descriptions of such circuits. This includes, but is not limited to one or more elements of system 100, system 200, memory device 400, memory device 500, memory device 600, memory device 700, system 800, memory device stack 900, memory device stack 1000, system 1900, and their components. These software descriptions may be: behavioral, register transfer, logic component, transistor, and layout geometry-level descriptions. Moreover, the software descriptions may be stored on storage media or communicated by carrier waves.

Data formats in which such descriptions may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email. Note that physical files may be implemented on machine-readable media such as: 4 mm magnetic tape, 8 mm magnetic tape, 3½ inch floppy media, CDs, DVDs, and so on.

FIG. 21 is a block diagram illustrating one embodiment of a processing system 2100 for including, processing, or generating, a representation of a circuit component 2120. Processing system 2100 includes one or more processors 2102, a memory 2104, and one or more communications devices 2106. Processors 2102, memory 2104, and communications devices 2106 communicate using any suitable type, number, and/or configuration of wired and/or wireless connections 2108.

Processors 2102 execute instructions of one or more processes 2112 stored in a memory 2104 to process and/or generate circuit component 2120 responsive to user inputs 2114 and parameters 2116. Processes 2112 may be any suitable electronic design automation (EDA) tool or portion thereof used to design, simulate, analyze, and/or verify electronic circuitry and/or generate photomasks for electronic circuitry. Representation 2120 includes data that describes all or portions of system 100, system 200, memory device 400, memory device 500, memory device 600, memory device 700, system 800, memory device stack 900, memory device stack 1000, system 1900, and their components, as shown in the Figures.

Representation 2120 may include one or more of behavioral, register transfer, logic component, transistor, and layout geometry-level descriptions. Moreover, representation 2120 may be stored on storage media or communicated by carrier waves.

Data formats in which representation 2120 may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email

User inputs 2114 may comprise input parameters from a keyboard, mouse, voice recognition interface, microphone and speakers, graphical display, touch screen, or other type of user interface device. This user interface may be distributed among multiple interface devices. Parameters 2116 may include specifications and/or characteristics that are input to help define representation 2120. For example, parameters 2116 may include information that defines device types (e.g., NFET, PFET, etc.), topology (e.g., block diagrams, circuit descriptions, schematics, etc.), and/or device descriptions (e.g., device properties, device dimensions, power supply voltages, simulation temperatures, simulation models, etc.).

Memory 2104 includes any suitable type, number, and/or configuration of non-transitory computer-readable storage media that stores processes 2112, user inputs 2114, parameters 2116, and circuit component 2120.

Communications devices 2106 include any suitable type, number, and/or configuration of wired and/or wireless devices that transmit information from processing system 2100 to another processing or storage system (not shown) and/or receive information from another processing or storage system (not shown). For example, communications devices 2106 may transmit circuit component 2120 to another system. Communications devices 2106 may receive processes 2112, user inputs 2114, parameters 2116, and/or circuit component 2120 and cause processes 2112, user inputs 2114, parameters 2116, and/or circuit component 2120 to be stored in memory 2104.

Implementations discussed herein include, but are not limited to, the following examples:

Example 1: An assembly, comprising: a first memory channel interface comprising a first command/address (CA) interface, a first lower data byte interface, and a first upper data byte interface; a second memory channel interface comprising a second CA interface, a second lower data byte interface, and a second upper data byte interface; a first two memory integrated circuits electrically coupled to the first CA interface and being stacked with a second two memory integrated circuits, the second two memory integrated circuits electrically coupled to the second CA interface; the first two memory integrated circuits configurable to use different ones of the first lower data byte interface and the first upper data byte interface; the second two memory integrated circuits configurable to use different ones of the second lower data byte interface and the second upper data byte interface; and a third memory integrated circuit, electrically coupled to the first CA interface and the second CA interface, and being stacked with the first two memory integrated circuits and the second two memory integrated circuits, a lower data byte interface of the third memory integrated circuit electrically coupled to the first lower data byte interface, an upper data byte interface of the third memory integrated circuit electrically coupled to the second lower data byte interface.

Example 2: The assembly of example 1, wherein the first CA interface and the second CA interface are time multiplexed on a same set of physical connections.

Example 3: The assembly of example 1, wherein a first one of the first two memory integrated circuits is to, in response a first CA command, communicate a first data burst via the first lower data byte interface and a second one of the first two memory integrated circuits is to, in response to the first CA command, communicate a second data burst via the first upper data byte interface, wherein the first data burst and the second data burst are communicated concurrently.

Example 4: The assembly of example 3, wherein the third memory integrated circuit is to, in response to the first CA command, communicate a third data burst after a one of the first data burst and the second data burst.

Example 5: The assembly of example 1, wherein a first one of the first two memory integrated circuits is to, in response a first CA command, communicate a first portion of a first data burst via the first lower data byte interface and a second portion of the first data burst via the first upper data byte interface and a second one of the first two memory integrated circuits is to, in response to the first CA command, communicate a second data burst via the first upper data byte interface, wherein the first portion of the first data burst and a first portion of the second data burst are communicated concurrently.

Example 6: The assembly of example 5, wherein the third memory integrated circuit is to, in response to the first CA command, communicate a third data burst after the first portion of the first data burst.

Example 7: The assembly of example 1, wherein, during a read data burst performed in response to a read command communicated via the first CA interface, the third memory integrated circuit is to transmit a read data strobe signal to the first two memory integrated circuits.

Example 8: The assembly of example 7, wherein, during the read data burst, the first two memory integrated circuits are to not transmit read data strobe signals.

Example 9: An integrated circuit stack, comprising: a first external command/address (CA) interface to receive commands and addresses from a device external to the integrated circuit stack; a second external CA interface to receive commands and addresses from the device external to the integrated circuit stack; a first data interface to communicate data with the device external to the integrated circuit stack in response to commands and addresses received via the first external CA interface; a second data interface to communicate data with the device external to the integrated circuit stack in response to commands and addresses received via the first external CA interface; a third data interface to communicate data with the device external to the integrated circuit stack in response to commands and addresses received via second first external CA interface; a fourth data interface to communicate data with the device external to the integrated circuit stack in response to commands and addresses received via the second external CA interface; a first memory device comprising at least a first memory array, the first memory device to receive commands and addresses via the first external CA interface, the first memory device configurable to communicate data via the first data interface; a second memory device comprising at least a second memory array, the second memory device to receive commands and addresses via the first external CA interface, the second memory device configurable to communicate data via the second data interface; a third memory device comprising at least a third memory array, the third memory device to receive commands and addresses via the second external CA interface, the third memory device configurable to communicate data via the third data interface; a fourth memory device comprising at least a fourth memory array, the fourth memory device to receive commands and addresses via the second external CA interface, the fourth memory device configurable to communicate data via the fourth data interface; and a fifth memory device comprising at least a fifth memory array, the fifth memory device to receive commands and addresses via the first external CA interface and the second external CA interface, the fifth memory device to, in response to commands received via the first external CA interface, communicate data via the first data interface, the fifth memory device to, in response to commands received via the second external CA interface, communicate data via the third data interface.

Example 10: The integrated circuit stack of example 9, wherein the first external CA interface and the second external CA interface are time multiplexed on a same set of physical connections.

Example 11: The integrated circuit stack of example 9, wherein the first memory device is to, in response a first CA command received via the first external CA interface, communicate a first data burst via the first data interface and the second memory device is to, in response to the first CA command, communicate a second data burst via the second data interface, wherein the first data burst and the second data burst are communicated concurrently.

Example 12: The integrated circuit stack of example 11, wherein the third memory device is to, in response to the first CA command, communicate a third data burst on the first data interface after the first data burst is complete.

Example 13: The integrated circuit stack of example 9, wherein the first memory device is to, in response a first CA command received via the first external CA interface, communicate a first subset of a first data burst via the first data interface and the second memory device is to, in response to the first CA command, communicate a second data burst via the second data interface, wherein the first subset of the first data burst and a second subset of the second data burst are communicated concurrently.

Example 14: The integrated circuit stack of example 13, wherein the third memory device is to, in response to the first CA command, communicate a third data burst via the first data interface after the first subset of the first data burst.

Example 15: The integrated circuit stack of example 9, wherein, during a read data burst performed in response to a read command communicated via the first CA interface, the third memory device is to transmit a read data strobe signal to the first memory device and the second memory device.

Example 16: A method of operating an integrated circuit stack, comprising: receiving, via a first external command/address (CA) interface, a first command from a device external to the integrated circuit stack; receiving, via a second external CA interface, a second command from the device external to the integrated circuit stack; in response to the first command, communicating, via a first data interface and by a first memory device in the integrated circuit stack, first data with the device external to the integrated circuit stack; in response to the first command, communicating, via a second data interface and by a second memory device in the integrated circuit stack, second data with the device external to the integrated circuit stack; in response to the second command, communicating, via a third data interface and by a third memory device in the integrated circuit stack, third data with the device external to the integrated circuit stack; in response to the second command, communicating, via a fourth data interface and by a fourth memory device in the integrated circuit stack, fourth data with the device external to the integrated circuit stack; in response to the first command, communicating, via the first data interface and by a fifth memory device in the integrated circuit stack, fifth data with the device external to the integrated circuit stack; and in response to the second command, communicating, via the third data interface and by the fifth memory device in the integrated circuit stack, sixth data with the device external to the integrated circuit stack.

Example 17: The method of example 16, wherein the first data and the second data are communicated concurrently.

Example 18: The method of example 16, wherein after the fifth data burst is communicated via the first data interface after the first data has been communicated via the first data interface.

Example 19: The example of example 16, further comprising: storing, in the fifth memory device, at least one check symbol.

Example 20: The method of example 19, further comprising: detecting an error on the first data interface associated with the first memory device; and configuring the first memory device to not use the first data interface.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. An assembly, comprising:
a first memory channel interface comprising a first command/address (CA) interface, a first lower data byte interface, and a first upper data byte interface;
a second memory channel interface comprising a second CA interface, a second lower data byte interface, and a second upper data byte interface;
a first two memory integrated circuits electrically coupled to the first CA interface and being stacked with a second two memory integrated circuits, the second two memory integrated circuits electrically coupled to the second CA interface;
the first two memory integrated circuits configurable to use different ones of the first lower data byte interface and the first upper data byte interface;
the second two memory integrated circuits configurable to use different ones of the second lower data byte interface and the second upper data byte interface; and
a third memory integrated circuit, electrically coupled to the first CA interface and the second CA interface, and being stacked with the first two memory integrated circuits and the second two memory integrated circuits, a lower data byte interface of the third memory integrated circuit electrically coupled to the first lower data byte interface, an upper data byte interface of the third memory integrated circuit electrically coupled to the second lower data byte interface.

2. The assembly of claim 1, wherein the first CA interface and the second CA interface are time multiplexed on a same set of physical connections.

3. The assembly of claim 1, wherein a first one of the first two memory integrated circuits is to, in response a first CA command, communicate a first data burst via the first lower data byte interface and a second one of the first two memory integrated circuits is to, in response to the first CA command, communicate a second data burst via the first upper data byte interface, wherein the first data burst and the second data burst are communicated concurrently.

4. The assembly of claim 3, wherein the third memory integrated circuit is to, in response to the first CA command, communicate a third data burst after a one of the first data burst and the second data burst.

5. The assembly of claim 1, wherein a first one of the first two memory integrated circuits is to, in response a first CA command, communicate a first portion of a first data burst via the first lower data byte interface and a second portion of the first data burst via the first upper data byte interface and a second one of the first two memory integrated circuits is to, in response to the first CA command, communicate a second data burst via the first upper data byte interface, wherein the first portion of the first data burst and a first portion of the second data burst are communicated concurrently.

6. The assembly of claim 5, wherein the third memory integrated circuit is to, in response to the first CA command, communicate a third data burst after the first portion of the first data burst.

7. The assembly of claim 1, wherein, during a read data burst performed in response to a read command communicated via the first CA interface, the third memory integrated circuit is to transmit a read data strobe signal to the first two memory integrated circuits.

8. The assembly of claim 7, wherein, during the read data burst, the first two memory integrated circuits are to not transmit read data strobe signals.

9. An integrated circuit stack, comprising:
a first external command/address (CA) interface to receive commands and addresses from a device external to the integrated circuit stack;
a second external CA interface to receive commands and addresses from the device external to the integrated circuit stack;
a first data interface to communicate data with the device external to the integrated circuit stack in response to commands and addresses received via the first external CA interface;
a second data interface to communicate data with the device external to the integrated circuit stack in response to commands and addresses received via the first external CA interface;
a third data interface to communicate data with the device external to the integrated circuit stack in response to commands and addresses received via the second external CA interface;
a fourth data interface to communicate data with the device external to the integrated circuit stack in response to commands and addresses received via the second external CA interface;
a first memory device comprising at least a first memory array, the first memory device to receive commands and addresses via the first external CA interface, the first memory device configurable to communicate data via the first data interface;
a second memory device comprising at least a second memory array, the second memory device to receive commands and addresses via the first external CA interface, the second memory device configurable to communicate data via the second data interface;
a third memory device comprising at least a third memory array, the third memory device to receive commands and addresses via the second external CA interface, the third memory device configurable to communicate data via the third data interface;
a fourth memory device comprising at least a fourth memory array, the fourth memory device to receive commands and addresses via the second external CA interface, the fourth memory device configurable to communicate data via the fourth data interface; and
a fifth memory device comprising at least a fifth memory array, the fifth memory device to receive commands and addresses via the first external CA interface and the second external CA interface, the fifth memory device to, in response to commands received via the first external CA interface, communicate data via the first data interface, the fifth memory device to, in response to commands received via the second external CA interface, communicate data via the third data interface.

10. The integrated circuit stack of claim 9, wherein the first external CA interface and the second external CA interface are time multiplexed on a same set of physical connections.

11. The integrated circuit stack of claim 9, wherein the first memory device is to, in response a first CA command received via the first external CA interface, communicate a first data burst via the first data interface and the second memory device is to, in response to the first CA command, communicate a second data burst via the second data interface, wherein the first data burst and the second data burst are communicated concurrently.

12. The integrated circuit stack of claim 11, wherein the third memory device is to, in response to the first CA command, communicate a third data burst on the first data interface after the first data burst is complete.

13. The integrated circuit stack of claim 9, wherein the first memory device is to, in response a first CA command received via the first external CA interface, communicate a first subset of a first data burst via the first data interface and the second memory device is to, in response to the first CA command, communicate a second data burst via the second data interface, wherein the first subset of the first data burst and a second subset of the second data burst are communicated concurrently.

14. The integrated circuit stack of claim 13, wherein the third memory device is to, in response to the first CA command, communicate a third data burst via the first data interface after the first subset of the first data burst.

15. The integrated circuit stack of claim 9, wherein, during a read data burst performed in response to a read command communicated via the first CA interface, the third memory device is to transmit a read data strobe signal to the first memory device and the second memory device.

16. A method of operating an integrated circuit stack, comprising:
receiving, via a first external command/address (CA) interface, a first command from a device external to the integrated circuit stack;
receiving, via a second external CA interface, a second command from the device external to the integrated circuit stack;
in response to the first command, communicating, via a first data interface and by a first memory device in the integrated circuit stack, first data with the device external to the integrated circuit stack;
in response to the first command, communicating, via a second data interface and by a second memory device in the integrated circuit stack, second data with the device external to the integrated circuit stack;
in response to the second command, communicating, via a third data interface and by a third memory device in the integrated circuit stack, third data with the device external to the integrated circuit stack;
in response to the second command, communicating, via a fourth data interface and by a fourth memory device in the integrated circuit stack, fourth data with the device external to the integrated circuit stack;
in response to the first command, communicating, via the first data interface and by a fifth memory device in the integrated circuit stack, fifth data with the device external to the integrated circuit stack; and
in response to the second command, communicating, via the third data interface and by the fifth memory device in the integrated circuit stack, sixth data with the device external to the integrated circuit stack.

17. The method of claim 16, wherein the first data and the second data are communicated concurrently.

18. The method of claim 16, wherein after the fifth data burst is communicated via the first data interface after the first data has been communicated via the first data interface.

19. The method of claim 16, further comprising:
storing, in the fifth memory device, at least one check symbol.

20. The method of claim 19, further comprising:
detecting an error on the first data interface associated with the first memory device; and
configuring the first memory device to not use the first data interface.
